(19) United States
(12) Patent Application Publication
(10) Pub. No.: US 2026/0033069 A1
(43) Pub. Date: Jan. 29, 2026

(54) DISPLAY DEVICE

(71) Applicant: LG Display Co., Ltd., Seoul (KR)

(72) Inventors: Jae Yong YUN, Paju-si (KR); Kyoung June JUNG, Paju-si (KR); Hae Sung LEE, Paju-si (KR)

(73) Assignee: LG Display Co., Ltd., Seoul (KR)

(21) Appl. No.: 19/255,698

(22) Filed: Jun. 30, 2025

(30) Foreign Application Priority Data
Jul. 24, 2024 (KR) 10-2024-0097920

(51) Int. Cl. H10H 29/41; H10H 29/37

(52) U.S. Cl. CPC H10H 29/41; H10H 29/37

(57) ABSTRACT

A display device can include a substrate including a display region and a non-display region, a plurality of light-emitting elements disposed on the substrate, and a plurality of stopper layers disposed under or on the light-emitting elements. At least one of the plurality of stopper layers includes a stopper region disposed in the non-display region. The display device can further include a pixel driving circuit disposed on the substrate and electrically connected to the light-emitting elements. The stopper layers are further disposed under or on the pixel driving circuit.

### CROSS-REFERENCE TO RELATED APPLICATION

This application claims priority to Korean Patent Application No. 10-2024-0097920, filed in the Republic of Korea on Jul. 24, 2024, the disclosure of which is hereby expressly incorporated by reference in its entirety for all purposes, as if fully set forth herein into the present application.

### BACKGROUND

### 1. Technical Field

The present disclosure relates to a display device.

### 2. Discussion of the Related Art

Display devices include an organic light-emitting display (OLED) device which emits light by itself, a liquid crystal display (LCD) device which requires a separate light source, and the like.

Recently, display devices including light-emitting elements (light-emitting diodes, LEDs) are attracting attention as next generation display devices. The light-emitting elements are formed of an inorganic material rather than an organic material, and thus the display devices including the light-emitting elements can have a faster lighting speed and more excellent emission efficiency, and display an image of higher brightness compared to an LCD device or OLED device.

The description provided in the background section should not be assumed to be prior art merely because it is mentioned in or associated with the background section. The background section can include information that describes one or more aspects of the subject technology.

### SUMMARY OF THE DISCLOSURE

An example embodiment of the present disclosure is directed to providing a display device whose reliability and yield can be enhanced.

A display device according to one example embodiment of the present disclosure can include: a substrate including a display region and a non-display region; a pixel driving circuit disposed on the substrate; a plurality of light-emitting elements disposed on the substrate and electrically connected to the pixel driving circuit; an optical layer disposed on the substrate and located on side surfaces of the plurality of light-emitting elements; and a plurality of stopper layers disposed under the pixel driving circuit, between the pixel driving circuit and the plurality of light-emitting elements, and in at least one of the display region and the non-display region under and on the light-emitting elements, wherein at least one of the plurality of stopper layers includes a stopper region disposed in the non-display region.

A display device according to another example embodiment of the present disclosure can include: a substrate including a display region and a non-display region; a first stopper layer disposed on the substrate and having a first stopper region in the non-display region; a pixel driving circuit disposed on the first stopper layer and a first insulating layer disposed on the first stopper layer; a second stopper layer disposed on the first insulating layer and having a second stopper region in the non-display region; a second insulating layer disposed on the second stopper layer; a third stopper layer disposed on the second insulating layer and having a third stopper region in the non-display region; a plurality of light-emitting elements disposed on the third stopper layer and electrically connected to the pixel driving circuit; an optical layer disposed on the third stopper layer; and a fourth stopper layer disposed on the optical layer and having a fourth stopper region in the non-display region.

The objects according to example embodiments of the present disclosure are not limited to the above-described objects, and other objects that are not mentioned will be clearly understood by those skilled in the art from the following description.

### BRIEF DESCRIPTION OF THE DRAWINGS

The following drawings attached to this disclosure illustrate preferred embodiments of the present disclosure and, together with the detailed description of the invention to be described below, serve to further understand the technical idea of the present disclosure, and therefore the present disclosure should not be construed as being limited to matters described in such drawings, in which:

FIG. 1 is an exploded perspective view of a display device according to one example embodiment of the present disclosure;

FIG. 2 is a plan view of a display device according to one example embodiment of the present disclosure;

FIG. 3 is an enlarged view of a display device according to one example embodiment of the present disclosure;

FIG. 4 is an enlarged plan view of a connection structure of a display device according to one example embodiment of the present disclosure;

FIG. 5 is a diagram illustrating a circuit structure according to an example embodiment of the present disclosure.

FIG. 6 is an enlarged view of a display device according to one example embodiment of the present disclosure;

FIG. 7 is a plan view of a display device according to an example embodiment of the present disclosure.

FIG. 8 is a plan view of a display device according to an example embodiment of the present disclosure.

FIG. 9 is a cross-sectional view of a display device according to an example embodiment of the present disclosure.

FIG. 10 is an enlarged cross-sectional view of a display device according to an example embodiment of the present disclosure.

FIG. 11 is an enlarged plan view of portion A of FIG. 3 according to one example embodiment of the present disclosure;

FIG. 12 is a cross-sectional view of the display device according to one example embodiment of the present disclosure;

FIG. 13 is an enlarged cross-sectional view of portion B in FIG. 12;

FIG. 14 is a plan view of a display device according to another example embodiment of the present disclosure;

FIG. 15 is a cross-sectional view of the display device according to another example embodiment of the present disclosure;

FIG. 16 is an enlarged cross-sectional view of portion C in FIG. 15;

FIG. 17 is an enlarged cross-sectional view of a display device according to still another example embodiment of the present disclosure;

FIG. 18 is an enlarged cross-sectional view of a display device according to yet another example embodiment of the present disclosure; and

FIGS. 19 to 22 are views showing devices to which the display devices according to example embodiments of the present disclosure are applied.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

The advantages and features of the present disclosure, and methods of achieving them will become apparent upon reference to the embodiments described in detail below in conjunction with the accompanying drawings. However, the present disclosure is not limited to the following embodiments disclosed herein, but can be implemented in various different forms; rather, the present embodiments are provided to make the disclosure of the present disclosure complete and to enable those skilled in the art to fully comprehend the scope of the present disclosure.

The shapes (e.g., sizes, lengths, widths, heights, thicknesses, locations, radii, diameters, and areas), proportions, angles, numbers, and the like of elements shown in the drawings to illustrate embodiments of the present disclosure are merely illustrative and are not intended to be limiting. Identical reference numerals can designate identical components throughout the description. Further, in describing the present disclosure, detailed descriptions of related known technologies can be omitted so as not to obscure the essence of the present disclosure. Terms such as, “including,” “having,” or “comprising” as used herein are generally intended to allow for the addition of other components, unless the terms are used with the term “only.” References to components of a singular noun include the plural of that noun, unless specifically stated otherwise.

In the interpretation of components, they are construed to include margins of error, even if not explicitly stated. Any implementation described herein as an “example” is not necessarily to be construed as preferred or advantageous over other implementations.

When describing a positional relationship, for example, “on,” “over,” “under,” “on top of,” “above,” “below,” “next to,” “adjacent to,” etc. describes the positional relationship of two parts, one or more other parts can be located between the two parts, unless “immediately,” “directly,” or “near to” is used.

When describing a temporal relationship, “after,” “following,” “next to,” or “before” describes a temporal antecedent or consequent relationship, which may not be continuous unless “immediately” or “directly” is used.

The terms, such as “below,” “lower,” “above,” “upper” and the like, can be used herein to describe a relationship between element(s) as illustrated in the drawings. It will be understood that the terms are spatially relative and based on the orientation depicted in the drawings.

The first, the second, and so on are used to describe various components, but these components are not limited by these terms. These terms are used only to distinguish one component from another. Therefore, the first component referred to below can be a second component within the technical spirit of the present disclosure.

Terms such as first, second, A, B, (a), or (b) can be used to describe elements of the present disclosure. Such terms are intended only to distinguish one component from another and are not intended to define the nature, sequence, order, or number of such components.

When a component is described as being “connected,” “coupled,” “accessed,” or “attached” to another component, it is to be understood that the component can be directly connected, coupled, accessed, or attached to the other component, but that there can also be other components interposed between the respective components which can be indirectly connected, coupled, accessed, or attached, unless specifically stated otherwise.

When a component is described as being “in contacted” or “overlapped” with another component, it is to be understood that the component can be in direct contacted or overlap with the other component, but that there can also be other components “interposed” between the respective components which can be in direct or indirect contacted or overlap with, unless specifically stated otherwise.

It should be understood that the term “at least one” includes all possible combinations of one or more related components. For example, the meaning of “at least one of the first, second, and third components” can be understood to include not only the first, second, or third component, but also any combination of two or more of the first, second, and third components.

The terms the first direction, the second direction, the third direction, the X-axis direction, the Y-axis direction, and the Z-axis direction are not to be interpreted solely as a geometric relationship in which the relationship to one another is perpendicular, but can refer to a broader range of orientations in which the configurations of the present disclosure can function.

Each of the features of various example embodiments of the present disclosure can be coupled or combined with one another in whole or in part, and can be technologically interlocked and operated in various ways, and each of the embodiments can be carried out independently or in conjunction with one another.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning, for example, consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings and coverages of the term “may” and vice versa.

Hereinafter, various example embodiments of the present disclosure will be described in detail with reference to the accompanying drawings. All the components of each display device/apparatus according to all embodiments of the present disclosure are operatively coupled and configured.

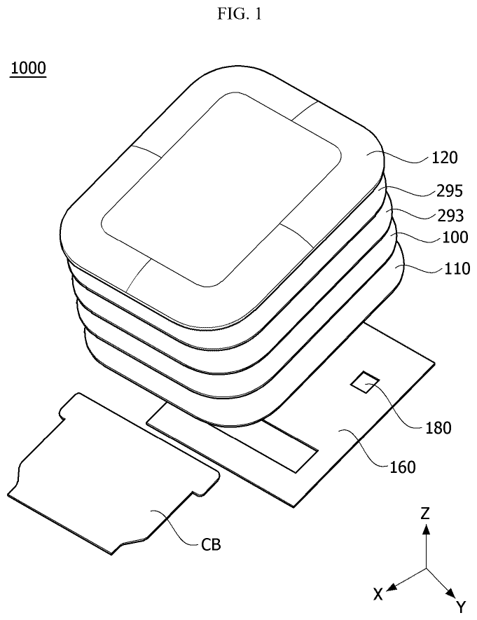

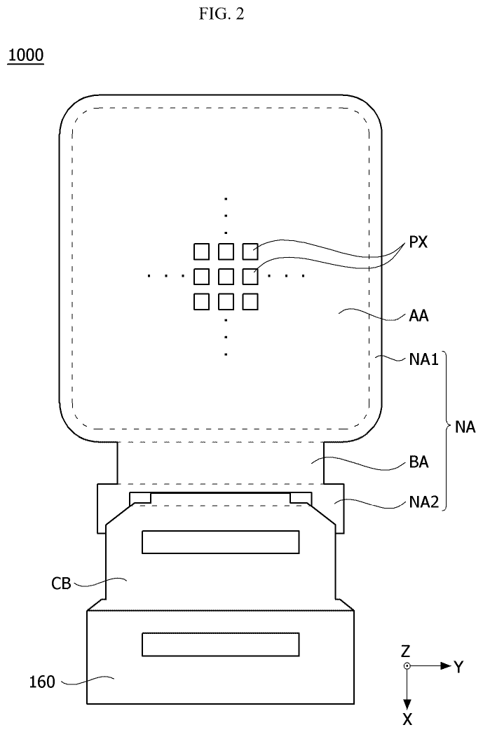

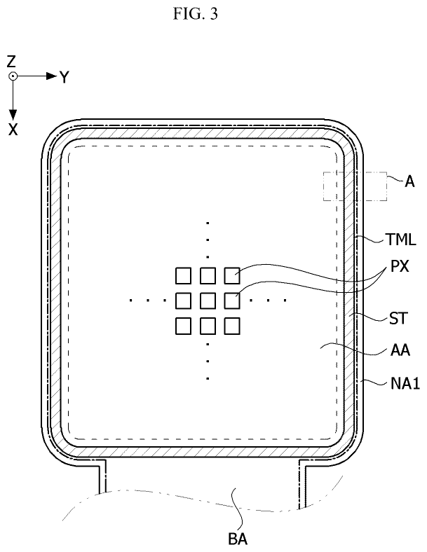

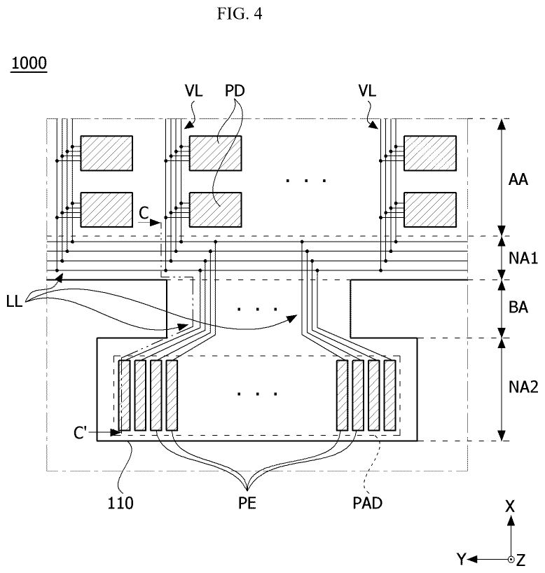

FIG. 1 is an exploded perspective view of a display device according to one example embodiment of the present disclosure. FIG. 2 is a plan view of a display device according to one example embodiment of the present disclosure. FIG. 3 is an enlarged view of a display device according to one example embodiment of the present disclosure. FIG. 4 is an enlarged plan view of a connection structure of a display device according to one example embodiment of the present disclosure.

Referring to FIGS. 1 to 3, a display device 1000 according to one example embodiment of the present disclosure can include a display panel 100, a polarizing layer 293, an adhesive layer 295, a cover member 120, a support substrate 110, a flexible circuit board CB, and a printed circuit board 160. Embodiments are not limited thereto. As an example, at least one of the above-mentioned components can be omitted, or at least one additional component can be further included.

For example, the display device 1000 can include a substrate 110. The substrate 110 can be a member that supports other components of the display device 1000. The substrate 110 can be made of an insulating material. For example, the substrate 110 can be made of glass, resin, or the like. Additionally, the substrate 110 can be made of a material having flexibility. For example, the substrate 110 can be made of a flexible plastic material such as polyimide (PI) or the like. However, the embodiments of the present disclosure are not limited thereto. As an example, the substrate 110 can be made of a rigid material or a flexible material. As an example, the substrate 110 can include one single layer or two or more layers. As an example, the substrate 110 can include an organic material or an inorganic material. As an example, the e substrate 110 can include a transparent material or an opaque material.

The display panel 100 can implement information, video, and/or an image provided to a user. For example, the display panel 100 can include a display area (or active area) AA and a non-display area (or non-active area) NA. For example, the substrate 110 can include the display area AA and the non-display area NA. The display area AA and non-display area NA are not limited to being described only with respect to the substrate 110 but can be described throughout the entire display device 1000.

The display area AA can be an area in which an image is displayed. The display area AA can include a plurality of pixels PX. Each of the plurality of pixels PX can be composed of a plurality of sub-pixels. A plurality of micro-LEDs can be respectively arranged in the plurality of sub-pixels. The plurality of micro-LEDs can be configured differently depending on the type of display device 1000.

The non-display area NA can be an area in which no image is displayed. Various wires and circuits for driving the plurality of pixels PX of the display area AA can be positioned in the non-display area NA. For example, in the non-display area NA, various wires and driving circuits can be mounted, and a pad portion PAD to which an integrated circuit, a printed circuit, and the like are connected can be provided, but the embodiments of the present disclosure are not limited thereto. As an example, the non-display area NA can be extended from the display area AA. As an example, the non-display area NA can fully or partially surround the display area AA, without being limited thereto. As an example, the non-display area NA can be at least partially or entirely invisible from a front side of the display panel 100, for example, by being bent toward a rear side of the display panel 100, without being limited thereto.

For example, the driving circuit can be a data driving circuit and/or a gate driving circuit, but the embodiments of the present disclosure are not limited thereto. Wires through which a control signal for controlling the driving circuits is supplied can be provided. For example, the control signal can include various timing signals including a clock signal, an input data enable signal, and synchronization signals, but the embodiments of the present disclosure are not limited thereto. The control signal can be received through the pad portion PAD. For example, link wires LL for transmitting signals can be positioned in the non-display area NA. For example, the pad portion PAD can be connected to driving components such as the flexible circuit board CB and the printed circuit board 160.

The non-display area NA can include a first non-display area NA1, a bending area BA, and a second non-display area NA2. For example, the first non-display area NA1 can be an area that surrounds at least a portion of the display area AA. The bending area BA can be an area extending from at least one of the plurality of sides of the first non-display area NA1, and can be a bendable area. The second non-display area NA2 can be an area extending from the bending area BA, and the pad portion PAD can be positioned in the second non-display area NA2. For example, the bending area BA can be in a bent state, and the remaining area of the substrate 110, excluding the bending area BA, can be in a flat state. In this case, as the bending area BA is in a bent state, the second non-display area NA2 can be positioned on the rear surface of the display area AA. However, the embodiments of the present disclosure are not limited thereto. As an example, the entire non-display area NA can be in a flat state, without being limited thereto.

The display area AA of the substrate 110 or the display device 1000 can be configured in various shapes depending on the design of the display device 1000. For example, the display area AA can be configured in a rectangular shape with four rounded corners, but the embodiments of the present disclosure are not limited thereto. In another example, the display area AA can be configured in a rectangular shape with four right-angled corners, a circular shape, or the like, but the embodiments of the present disclosure are not limited thereto.

According to the example embodiments of the present disclosure, the width of the second non-display area NA2 in which a plurality of pad electrodes PE are arranged can be greater than the width of the bending area BA in which only the plurality of link wires LL are arranged. Additionally, the width of the display area AA in which the plurality of sub-pixels are arranged can be greater than the width of the bending area BA in which only the plurality of link wires LL are arranged. In the drawings, the width of the bending area BA is illustrated as being smaller than that of other areas of the substrate 110. However, the shape of the substrate 110 including the bending area BA is merely example, and the embodiments of the present disclosure are not limited thereto. As an example, the width of the second non-display area NA2 in which a plurality of pad electrodes PE are arranged, the width of the bending area BA in which only the plurality of link wires LL are arranged, and other the width of areas of the substrate 110 can be the same as each other, or can be different from each other, without being limited thereto.

Referring to FIG. 3, in the display device according to an example embodiment of the present disclosure, a display area AA in which a plurality of pixels PX are disposed and a first non-display area NA1 surrounding the display area AA can be disposed. A crack stopper ST can be disposed in the first non-display area NA1 to surround the display area AA.

The crack stopper ST can serve to block a crack generated in the first non-display area NA from propagating to the display area AA during laser trimming. And, when viewed in a plan view, the crack stopper ST can have a closed loop shape surrounding the display area AA in the first non-display area NA1. The crack stopper ST can include first to fourth stopper openings 111c, 114a, 116a, and 118a of FIG. 12. However, the present disclosure is not limited thereto.

Furthermore, the first non-display area NA1 having the trimming margin line TML can be independently separated from the display area AA with the crack stopper ST as a boundary. For example, the inorganic layer on which the crack stopper ST is formed, for example, the first to fourth stopper layers 111, 114, 116, and 118 of FIG. 12, can be independently separated by the first to fourth stopper openings 111c, 114a, 116a, and 118a constituting the crack stopper ST.

Therefore, even if a crack occurs in the trimming line (TRL of FIG. 12) outside the trimming margin line TML of the first non-display area NA1 during laser trimming, the path through which the crack moves is narrowed or blocked and can less or cannot propagate to the display area AA because of the crack stopper ST. If the crack stopper ST is not integrally formed in the first non-display area NA1 but is formed only in a partial area, cracks generated during laser trimming can propagate to the display area AA through the inorganic layer portion on which the stopper ST is not formed.

Referring to FIG. 4, a plurality of pixel driving circuits PD can be arranged in the display area AA. The plurality of pixel driving circuits PD can be circuits for driving the micro-LEDs of the plurality of sub-pixels. Each of the plurality of pixel driving circuits PD can include a plurality of transistors including a driving transistor, a storage capacitor, and the like and can supply a control signal, power, and a driving current to the micro-LEDs of the plurality of sub-pixel to control the light emission operation of the plurality of micro-LEDs. For example, the pixel driving circuit PD can include a power wire and a signal wire for controlling the on/off state and/or light emission time of the micro-LED. For example, the plurality of pixel driving circuits PD can be a driving driver manufactured using a metal-oxide-silicon field effect transistor (MOSFET) fabrication process on a semiconductor substrate, but the embodiments of the present disclosure are not limited thereto. The driving driver can include the plurality of pixel driving circuits PD and can drive the plurality of sub-pixels.

Referring also to FIG. 1, the flexible circuit board CB and the printed circuit board 160 can be positioned below the display panel 100. The flexible circuit board CB and the printed circuit board 160 can be positioned on at least one edge of the display panel 100, but the embodiments of the present disclosure are not limited thereto.

One side of the flexible circuit board CB can be attached to the display panel 100, and the other side thereof can be attached to the printed circuit board 160, but embodiments of the present disclosure are not limited thereto. The flexible circuit board CB can be a flexible film, but embodiments of the present disclosure are not limited thereto.

The pad portion PAD including the plurality of pad electrodes PE can be positioned in the second non-display area NA2. Driving components, including one or more flexible circuit boards (or flexible films) CB and the printed circuit board 160, can be attached or bonded to the pad portion PAD. The plurality of pad electrodes PE of the pad portion PAD can be electrically connected to the one or more flexible circuit boards (or flexible films) CB, and can transmit various signals (or power) from the printed circuit board 160 and the flexible circuit board (or flexible film) CB to the plurality of pixel driving circuits PD of display area AA.

The flexible circuit board (or flexible film) CB can be a film in which various components are arranged on a base film having flexibility. For example, a driving IC, such as a gate driver IC or a data driver IC, can be positioned on the flexible circuit board (or flexible film) CB, but the embodiments of the present disclosure are not limited thereto.

The driving IC can be a component that processes data and a driving signal for displaying an image. The driving IC can be disposed by a method such as a chip-on-glass (COG) method, a chip-on-film (COF) method, a gate in panel (GIP) method, or a tape carrier package (TCP) method depending on a method of being mounted, but embodiments of the present disclosure are not limited thereto. The flexible circuit board (or flexible film) CB can be attached to or bonded on the plurality of pad electrodes PE through a conductive adhesive layer, but embodiments of the present disclosure are not limited thereto.

The printed circuit board 160 can be a component electrically connected to one or more flexible circuit boards (or flexible films) CB and supplying signals to the driving IC. The printed circuit board 160 can be disposed at one side of the flexible circuit board (or flexible film) CB and electrically connected to the flexible circuit board (or flexible film) CB. Various components for supplying various signals to the driving IC can be disposed on the printed circuit board 160. For example, various components, such as a timing controller, a power supply unit, a memory, a processor, etc., can be disposed on the printed circuit board 160. For example, the printed circuit board 160 can include a power management integrated circuit (PMIC), but embodiments of the present disclosure are not limited thereto.

The printed circuit board 160 can include at least one hole 180, but the embodiments of the present disclosure are not limited thereto. An internal component for sensing ambient light, temperature, or the like, which can be provided to a plurality of sensors, can be positioned in a region corresponding to the at least one hole 180. For example, the internal component can include an ambient light sensor (ALS), a temperature sensor, or the like, but the embodiments of the present disclosure are not limited thereto. For example, the hole 180 can be a transmission hole or the like, but the embodiments of the present disclosure are not limited thereto.

Referring to FIG. 1, the polarizing layer 293 can be positioned on the display panel 100. The polarizing layer 293 can prevent or reduce light generated from an external light source from entering the interior of the display panel 100 and affecting the micro-LEDs or the like.

The cover member 120 can be positioned on the polarizing layer 293. The cover member 120 can be a member for protecting the display panel 100. The adhesive layer 295 can be positioned between the polarizing layer 293 and the cover member 120. The cover member 120 can be attached to the display panel 100 by using the adhesive layer 295. The adhesive layer 295 can include an optically clear adhesive (OCA), an optically clear resin (OCR), a pressure sensitive adhesive (PSA), or the like, but the embodiments of the present disclosure are not limited thereto.

The support substrate 110 can be positioned between the display panel 100 and the printed circuit board 160. The support substrate 110 can reinforce the rigidity of the display panel 100. The support substrate 110 can be a back plate, but the embodiments of the present disclosure are not limited thereto.

Referring to FIGS. 1 to 4, the plurality of link wires LL can be arranged in the first and second non-display areas NA1 and NA2. The plurality of link wires LL can be wires for transmitting various signals from the one or more flexible circuit boards (or flexible films) CB and the printed circuit board 160 to the display area AA. The plurality of link wires LL can extend from the plurality of pad electrodes PE of the second non-display area NA2 toward the bending area BA and the first non-display area NA1, and can be electrically connected to a plurality of driving wires VL of the display area AA.

The plurality of pixel driving circuits PD can be driven by receiving signals from one or more flexible circuit boards (or flexible films) CB and the printed circuit board 160 through the driving wiring VL in the display area AA and the link wiring LL in the non-display area NA.

For example, a plurality of driving wires VL can be wires for transmitting a signal output from the flexible circuit board (or flexible film) CB and the printed circuit board 160 together with a plurality of link wires LL to a plurality of pixel driving circuits PD. A plurality of driving wires VL can be disposed in the display area AA and electrically connected to each of a plurality of pixel driving circuits PD. A plurality of driving wires VL can extend from the display area AA toward the non-display area NA and can be electrically connected to a plurality of link wires LL.

Therefore, the signal output from the flexible circuit board (or flexible film) CB and the printed circuit board 160 can be transmitted to each of the plurality of pixel driving circuits PD through the plurality of link lines LL and the plurality of driving lines VL.

As the bending area BA is bent, a portion of the plurality of link wires LL can also be bent together. Stress can be concentrated on a portion of the bent link wires LL, thereby causing cracks in the link wires LL. Accordingly, the plurality of link wires LL can be formed of a highly flexible conductive material to reduce cracks when the bending area BA is bent. For example, the plurality of link wires LL can be formed of a highly flexible conductive material, such as gold (Au), silver (Ag), or aluminum (Al), but the embodiments of the present disclosure are not limited thereto.

Additionally, as an example, the plurality of link wires LL can be formed of one of various conductive materials used in the display area AA. For example, the plurality of link wires LL can be made of molybdenum (Mo), chromium (Cr), titanium (Ti), nickel (Ni), neodymium (Nd), copper (Cu), an alloy of silver (Ag) and magnesium (Mg), or other alloys thereof, but the embodiments of the present disclosure are not limited thereto. The plurality of link wires LL can have a multilayer structure made of various conductive materials. For example, the plurality of link wires LL can have a triple-layer structure of titanium (Ti)/aluminum (Al)/titanium (Ti), but the embodiments of the present disclosure are not limited thereto.

As an example, a plurality of link wirings LL can be configured in various shapes to reduce stress. At least a portion of the plurality of link wirings LL disposed on the bending area BA can extend in the same direction as the extending direction of the bending area BA, or can extend in a direction different from the extending direction of the bending area BA to reduce stress. For example, when the bending area BA extends in one direction from the first non-display area NA1 to the second non-display area NA2, at least a portion of the link wiring LL disposed on the bending area BA can extend in a direction inclined to the one direction. For another example, at least a portion of the plurality of link lines LL can be configured in various shapes. For example, at least a portion of the plurality of link lines LL disposed on the bending area BA can have a shape in which a conductive pattern having at least one of a diamond shape, a rhombus shape, a trapezoidal shape, a triangular wave shape, a sawtooth wave shape, a sinusoidal shape, a circular shape, and an omega (Ω) shape is repeatedly arranged, but embodiments of the present disclosure are not limited thereto.

Therefore, in order to reduce or minimize the stress concentrated on the plurality of link lines LL and the corresponding crack, the shape of the plurality of link lines LL can be formed in various shapes including the above-described shape, but embodiments of the present disclosure are not limited thereto.

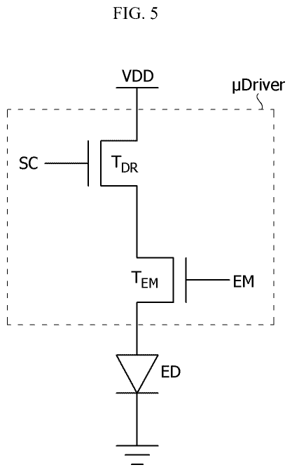

FIG. 5 is a diagram illustrating a circuit structure according to an example embodiment of the present disclosure.

Although FIG. 5 illustrates that one light emitting device ED is connected to the micro-driver, the present disclosure is not limited thereto. As an example, two or more light emitting devices ED can be connected to one micro-driver, or one light emitting devices ED can be connected to two or more micro-drivers, without being limited thereto. For example, eight light emitting devices ED can be connected to one micro-driver. For another example, 16 light emitting devices ED can be connected to one micro-driver, or 32 light emitting devices ED or 64 light emitting devices ED can be connected to one micro-driver at the same time. The light emitting device ED can be a micro-light emitting device μLED. Although the present disclosure is described mainly based on that the light emitting device ED is a micro-light emitting device, embodiments are not limited thereto. As an example, the light emitting device ED can be a light emitting diode, an organic light emitting diode, etc., without being limited thereto.

Referring to FIG. 5, for example, in the driving transistor T_{DR}, a high potential power voltage VDD can be applied to the first electrode, a first electrode of the light emitting transistor T_{EM} can be connected to the second electrode, and a scan signal SC can be applied to the gate electrode. The scan signal SC applied to the gate electrode of the driving transistor T_{DR} is a direct current power source, and a fixed reference voltage Vref can be applied to each frame, but embodiments of the present disclosure are not limited thereto. As an example, the scan signal SC applied to the gate electrode of the driving transistor TDR can be an alternating current power source, and a varied voltage can be applied to various period, without being limited thereto.

In the light emitting transistor T_{EM}, the second electrode of the driving transistor T_{DR} is connected to the first electrode, the light emitting device ED is connected to the second electrode, and the light emitting signal EM can be applied to the gate electrode. The light emitting signal EM applied to the gate electrode of the light emitting transistor T_{EM} can be a pulse width modulation signal that changes every frame, but embodiments of the present disclosure are not limited thereto.

In the light emitting device ED, as an example, the first electrode can be connected to the second electrode of the light emitting transistor T_{EM}, and the second electrode can be connected to the ground or a base voltage. For example, the first electrode can be an anode electrode and the second electrode can be a cathode electrode, but configurations of the present disclosure are not limited thereto.

Each of the driving transistor T_{DR} and the light emitting transistor T_{EM} can be an n-type transistor or a p-type transistor.

In the micro driver μDR, the driving transistor T_{DR} can be turned on by the scan signal SC applied from the timing controller T-CON, and the light emitting transistor T_{EM} can be turned on by the light emitting signal EM. As a result, the driving current is applied to the light emitting device ED via the driving transistor T_{DR} and the light emitting transistor T_{EM} by the high potential power voltage VDD applied to the first electrode of the driving transistor T_{DR}, and thus the light emitting device ED can emit light.

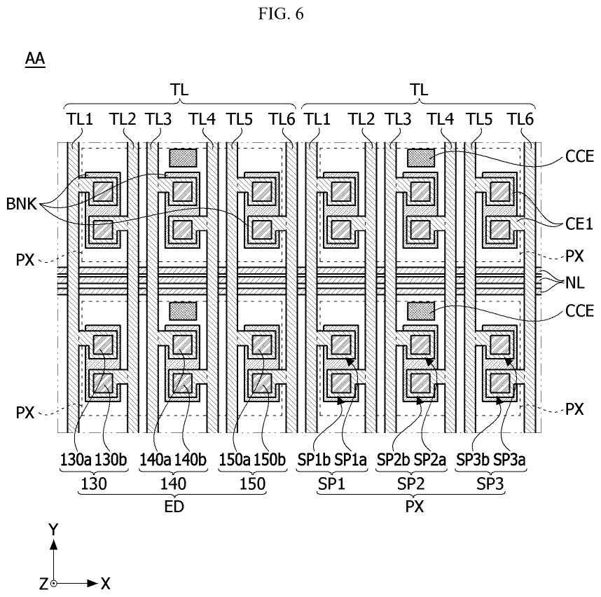

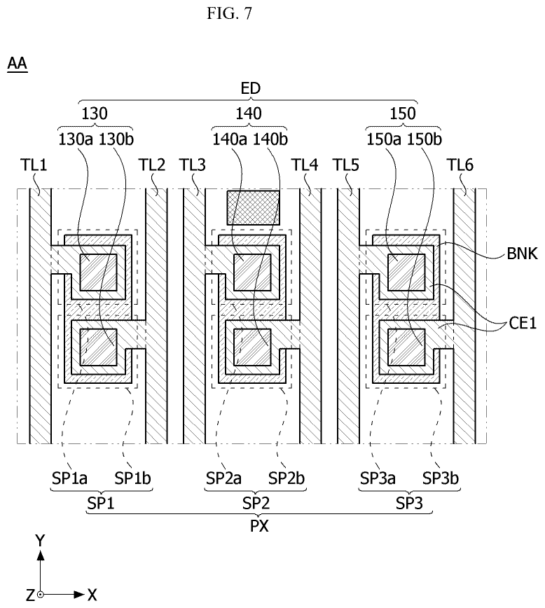

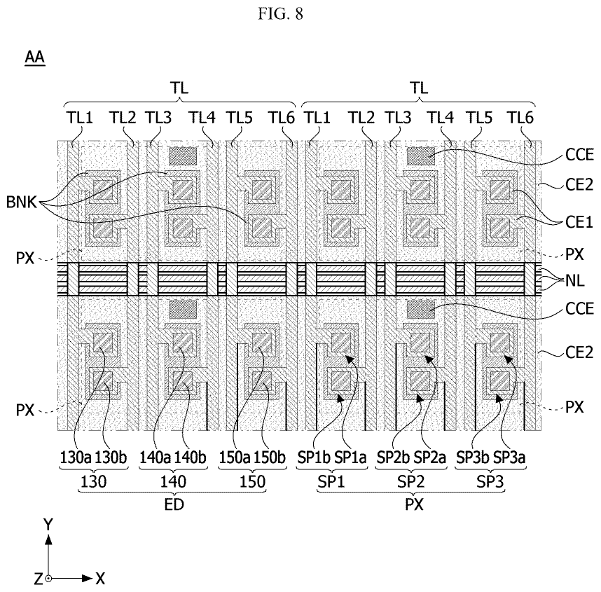

FIGS. 6 to 8 are plan views of a display device according to an example embodiment of the present disclosure. For example, FIG. 6 is an enlarged plan view of a display area including a plurality of pixels. For example, FIG. 6 is an enlarged plan view of a display area including one pixel. For example, FIG. 7 is an enlarged plan view of a display area including a plurality of pixels. In FIGS. 6 and 7, only a plurality of signal lines TL, a plurality of communication lines NL, a plurality of first electrodes CE1, a plurality of banks BNK, and a plurality of light emitting devices ED are illustrated, but embodiments of the present disclosure are not limited thereto. FIG. 8 is an enlarged plan view in which a plurality of second electrodes CE2 are additionally disposed in FIG. 6.

Referring to FIGS. 6 and 7, a plurality of pixels PX including a plurality of sub-pixels can be disposed in the display area AA. Each of the plurality of sub-pixels includes a light emitting device ED and can independently emit light. The plurality of sub-pixels can form a plurality of rows and a plurality of columns and can be arranged in a matrix form, but configurations of the present disclosure are not limited thereto.

A plurality of sub-pixels can include a first sub-pixel SP1, a second sub-pixel SP2, and a third sub-pixel SP3. For example, any one of the first sub-pixel SP1, the second sub-pixel SP2, and the third sub-pixel SP3 can be a red sub-pixel, the other can be a green sub-pixel, and the rest can be a blue sub-pixel. Types of a plurality of sub-pixels are examples, and embodiments of the present disclosure are not limited thereto. As an example, each pixel PX can include two or more, or four or more sub-pixels. As an example, the plurality of sub-pixels included in each pixel PX can emit light of different colors, or at least two of the plurality of sub-pixels included in each pixel PX can emit light of the same color. As an example, the plurality of sub-pixels included in each pixel PX can include a red sub-pixel, a green sub-pixel, and a blue sub-pixel. As an example, one or more sub-pixel emitting light of other colors such as white, Cyan, magenta, or yellow can be additionally or alternatively included, without being limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. The pair of first sub-pixels SP1 can include a 1-1 sub-pixel SP1a and a 1-2 sub-pixel SP1b. The pair of second sub-pixels SP2 can include a 2-1 sub-pixel SP2a and a 2-2 sub-pixel SP2b.

The pair of third sub-pixels SP3 can include a 3-1 sub-pixel SP3a and a 3-2 sub-pixel SP3b. For example, one pixel PX can include a 1-1 sub-pixel SP1a, a 1-2 sub-pixel SP1b, a 2-1 sub-pixel SP2b, a 3-1 sub-pixel SP3a, and a 3-2 sub-pixel SP3b, but embodiments of the present disclosure are not limited thereto.

A plurality of sub-pixels constituting one pixel PX can be variously arranged. For example, in one pixel PX, a pair of first sub-pixels SP1 can be disposed in the same column, a pair of second sub-pixels SP2 can be disposed in the same column, and a pair of third sub-pixels SP3 can be disposed in the same column. The first sub-pixel SP1, the second sub-pixel SP2, and the third sub-pixel SP3 can be disposed in the same row. The number and arrangement of a plurality of sub-pixels constituting one pixel PX are example, and configurations of the present disclosure are not limited thereto.

A plurality of signal lines TL can be disposed in a region between the plurality of sub-pixels. The plurality of signal lines TL can extend in a column direction between the plurality of sub-pixels. The plurality of signal lines TL can be lines that transmit an anode voltage from the pixel driving circuit PD to a plurality of sub-pixels. For example, the plurality of signal lines TL can be electrically connected to the plurality of pixel driving circuits PD and the first electrode CE1 of the plurality of sub-pixels.

The anode voltage output from the pixel driving circuit PD can be transferred to the first electrodes CE1 of a plurality of sub-pixels through a plurality of signal lines TL. For example, the first electrode CE1 can be an electrode electrically connected to the anode electrode 134 of the light emitting device ED. Accordingly, the anode voltage from the signal line TL can be transferred to the anode electrode 134 of the light emitting device ED through the first electrode CE1.

Accordingly, instead of forming a plurality of transistors and storage capacitors in each of the plurality of sub-pixels, the structure of the display device 1000 can be simplified by using the pixel driving circuit PD in which the plurality of pixel circuits are integrated. Further, as circuits disposed in each of the plurality of sub-pixels are integrated in one pixel driving circuit PD, high efficiency and low power driving can be possible.

A plurality of signal lines TL can include a first signal line TL1, a second signal line TL2, a third signal line TL3, a fourth signal line TL4, a fifth signal line TL5 and a sixth signal line TL6. Each of the first signal line TL1 and the second signal line TL2 can be electrically connected to each of a pair of first sub-pixels SP1. The third signal line TL3 and the fourth signal line TL4 can be electrically connected to each of a pair of second sub-pixels SP2. The fifth signal line TL5 and the sixth signal line TL6 can be electrically connected to each of a pair of third sub-pixels SP3.

As an example, the first signal wire TL1 can be positioned on one side of the pair of first sub-pixels SP1, and the second signal wire TL2 can be positioned on the other side of the pair of first sub-pixels SP1. The first signal wire TL1 can be electrically connected to the first electrode CE1 of one, e.g., the 1-1 sub-pixel SP1a, of the pair of first sub-pixels SP1. The second signal wire TL2 can be electrically connected to the first electrode CE1 of the other, e.g., the 1-2 sub-pixel SP1b, of the pair of first sub-pixels SP1. Embodiments are not limited thereto. As an example, the first signal wire TL1 and the second signal wire TL2 can be positioned on the same side of the pair of first sub-pixels SP1. As an example, one of the first signal wire TL1 and the second signal wire TL2 can be omitted, and the other of first signal wire TL1 and the second signal wire TL2 can be electrically connected to the first electrode CE1 of both of the pair of first sub-pixels SP1, without being limited thereto.

The third signal wire TL3 can be positioned on one side of the pair of second sub-pixels SP2, and the fourth signal wire TL4 can be positioned on the other side of the pair of second sub-pixels SP2. For example, the third signal wire TL3 can be positioned adjacent to the second signal wire TL2. The third signal wire TL3 can be electrically connected to the first electrode CE1 of one, e.g., the 2-1 sub-pixel SP2a, of the pair of second sub-pixels SP2. The fourth signal wire TL4 can be electrically connected to the first electrode CE1 of the other, e.g., the 2-2 sub-pixel SP2b, of the pair of second sub-pixels SP2.

The fifth signal wire TL5 can be positioned on one side of the pair of third sub-pixels SP3, and the sixth signal wire TL6 can be positioned on the other side of the pair of third sub-pixels SP3. For example, the fifth signal wire TL5 can be positioned adjacent to the fourth signal wire TL4. The sixth signal wire TL6 can be positioned adjacent to the first signal wire TL1, which is connected to an adjacent pixel PX. The fifth signal wire TL5 can be electrically connected to the first electrode CE1 of one, e.g., the 3-1 sub-pixel SP3a, of the pair of third sub-pixels SP3. The sixth signal wire TL6 can be electrically connected to the first electrode CE1 of the other, e.g., the 3-2 sub-pixel SP3b, of the pair of third sub-pixels SP3.

The plurality of signal wires TL can be made of a conductive material. For example, the plurality of signal wires TL can be formed of a conductive material, such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. In another example, the plurality of signal wires TL can have a multilayer structure of a conductive material. For example, the plurality of signal wires TL can have a multilayer structure of titanium (Ti)/aluminum (Al)/titanium (Ti)/indium tin oxide (ITO), but the embodiments of the present disclosure are not limited thereto.

The plurality of communication wires NL can be arranged in a region between the plurality of pixels PX. The plurality of communication wires NL can extend in a row direction in the region between the plurality of pixels PX. The plurality of communication wires NL can be arranged in a region between the plurality of second electrodes (CE2 in FIG. 8), and may not overlap the plurality of second electrodes CE2. For example, the plurality of communication wires NL can be wires used for short-range communication, such as near field communication (NFC). The plurality of communication wires NL can function as an antenna. For example, the plurality of communication wires NL can be a plurality of connection wires or the like, but the embodiments of the present disclosure are not limited thereto. As an example, the communication wires NL can be omitted depending on the design.

According to the example embodiments of the present disclosure, the bank BNK can be positioned in each of the plurality of sub-pixels. The plurality of banks can be structures on which the plurality of micro-LEDs are mounted. The plurality of banks can guide the positions of the plurality of micro-LEDs ED in a transfer process for transferring the plurality of micro-LEDs ED to the display device 1000. During the transfer process of the plurality of micro-LEDs ED, the plurality of micro-LEDs ED can be transferred onto the plurality of banks BNK. The plurality of banks BNK can be bank patterns or structures, but embodiments of present disclosure are not limited thereto.

The bank BNK of the first sub-pixel SP1, the bank BNK of the second sub-pixel SP2, and the bank BNK of the third sub-pixel SP3 can be spaced apart from each other. The bank BNK of the first sub-pixel SP1, the bank BNK of the second sub-pixel SP2, and the bank BNK of the third sub-pixel SP3 can be configured to be separated from each other. Accordingly, the banks BNK of the first sub-pixel SP1, the second sub-pixel SP2, and the third sub-pixel SP3, onto which different types of micro-LEDs ED are transferred, can be easily distinguished.

The bank BNK of the 1-1 sub-pixel SP1a and the bank BNK of the 1-2 sub-pixel SP1b can be connected to each other or can be formed to be spaced apart from each other. For example, a bank BNK of the 1-1 sub-pixel SP1a in which the same type of light emitting device ED is disposed and a bank BNK of the 1-2 sub-pixel SP1b can be connected to each other or can be spaced apart from each other or separated from each other in consideration of a design such as a transfer process requirement and the like. In addition, the bank BNK of the 3-1 sub-pixel SP3a and the bank BNK of the 3-2 sub-pixel SP3b can be connected to each other or can be formed to be spaced apart from each other.

Accordingly, the bank BNK of the pair of first sub-pixels SP1, the bank BNK of the pair of second sub-pixels SP2, and the bank BNK of the pair of third sub-pixels SP3 can be variously formed, and embodiments of the present disclosure are not limited thereto.

For example, the plurality of banks BNK can be formed of an organic insulating material. The plurality of banks BNK can be configured as a single layer or a multi-layer of the organic insulating material. For example, the plurality of banks BNK can be formed of a photoresist, polyimide (PI), or acryl-based material, but the embodiments of present disclosure are not limited thereto.

The first electrode CE1 can be positioned in each of the plurality of sub-pixels. The first electrode CE1 can be positioned on the bank BNK. For example, the first electrodes CE1 can be positioned on the top and side surfaces of the plurality of banks BNK, without being limited thereto. As an example, the first electrodes CE1 can be positioned on the top surface of the plurality of banks BNK, and may not be positioned on the side surfaces of the plurality of banks BNK, without being limited thereto.

As an example, at least a portion of the first electrode CE1 can extend outside of the bank BNK and be electrically connected to the signal wire TL closest to the first electrode CE1. For example, a portion of the first electrode CE1 of the 1-1 sub-pixel SP1a can extend to one side region of the 1-1 sub-pixel SP1a and be electrically connected to the first signal wire TL1, and a portion of the first electrode CE1 of the 1-2 sub-pixel SP1b can extend to the other side region of the 1-2 sub-pixel SP1b and be electrically connected to the second signal wire TL2. Embodiments are not limited thereto. As an example, the first electrode CE1 may not extend outside of the bank BNK, while the signal wire TL closest to the first electrode CE1 can extend onto the bank BNK to be electrically connected to the first electrode CE1, without being limited thereto. As an example, a separate electrode can be further provided to extend outside of the bank BNK, to electrically connect the signal wire TL and the first electrode CE1, without being limited thereto.

A portion of the first electrode CE1 of the 2-1 sub-pixel SP2a can extend to one side area of the 2-1 sub-pixel SP2a to be electrically connected to the third signal line TL3, and a portion of the first electrode CE1 of the 2-2 sub-pixel SP2b can extend to the other side area of the 2-2 sub-pixel SP2b to be electrically connected to the fourth signal line TL4. A portion of the first electrode CE1 of the 3-1 sub-pixel SP3a can extend to one side area of the 3-1 sub-pixel SP3a to be electrically connected to the fifth signal line TL5, and a portion of the first electrode CE1 of the 3-2 sub-pixel SP3b can extend to the other side area of the 3-2 sub-pixel SP3b to be electrically connected to the sixth signal line TL6.

The first electrode CE1 can be electrically connected to the anode electrode 134 of the micro-LED ED, and can transmit the anode voltage from the pixel driving circuit PD to the micro-LED ED of each of the plurality of sub-pixels through the signal wire TL. Different voltages can be applied to the respective first electrodes CE1 of the plurality of sub-pixels according to an image to be displayed. For example, different voltages can be applied to the respective first electrodes CE1 of the plurality of sub-pixels. Accordingly, the first electrode CE1 can be a pixel electrode, and the embodiments of the present disclosure are not limited thereto.

The first electrode CE1 can be formed of a conductive material. For example, the first electrode CE1 can be formed integrally with a plurality of signal lines TLs, or can be formed separately from the signal lines TLs. For example, the first electrode CE1 can be formed of the same conductive material as or a different material from a plurality of signal lines TLs, but embodiments of the present disclosure are not limited thereto. For example, the first electrode CE1 can be formed of a multi-layered structure of titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but embodiments of the present disclosure are not limited thereto. For another example, the first electrode CE1 can be formed of a multi-layered structure of a conductive material. For example, a plurality of first electrodes CE1 can be formed of a multi-layered structure of titanium (Ti)/aluminum (Al)/titanium (Ti)/indium tin oxide (ITO), but embodiments of the present disclosure are not limited thereto.

A light emitting device ED can be disposed in each of a plurality of sub-pixels. A plurality of light emitting devices ED can be any one of a light-emitting diode (LED) and a micro light-emitting diode (Micro LED), but embodiments of the present disclosure are not limited thereto. A plurality of light emitting devices ED can be disposed on the bank BNK and the first electrode CE1. A plurality of light emitting devices ED can be disposed on the first electrode CE1 and can be electrically connected to the first electrode CE1. Accordingly, the light emitting device ED can emit light by receiving the anode voltage from the pixel driving circuit PD through the signal line TL and the first electrode CE1.

The plurality of micro-LEDs ED can include a first micro-LED 130, a second micro-LED 140, and a third micro-LED 150. The first micro-LED 130 can be positioned in the first sub-pixel SP1. The second micro-LED 140 can be positioned in the second sub-pixel SP2. The third micro-LED 150 can be positioned in the third sub-pixel SP3. For example, one of the first micro-LED 130, the second micro-LED 140, and the third micro-LED 150 can be a red micro-LED, another one can be a green micro-LED, and the remaining one can be a blue micro-LED, but the embodiments of the present disclosure are not limited thereto. Accordingly, by combining red light, green light, and blue light emitted from the plurality of micro-LEDs ED, various colors of light including white can be implemented. The types of the plurality of micro-LEDs ED are merely example, and the embodiments of the present disclosure are not limited thereto.

The first light emitting device 130 can include a 1-1 light emitting device 130a disposed in the 1-1 sub-pixel SP1a and a 1-2 light emitting device 130b disposed in the 1-2 sub-pixel SP1b. The second light emitting device 140 can include a 2-1 light emitting device 140a disposed in the 2-1 sub-pixel SP2a and a 2-2 light emitting device 140b disposed in the 2-2 sub-pixel SP2b. The third light emitting device 150 can include a 3-1 light emitting device 150a disposed in the 3-1 sub-pixel SP3a and a 3-2 light emitting device 150b disposed in the 3-2 sub-pixel SP3b.

Referring to FIGS. 6 to 8, the second electrode CE2 can be positioned in each of the plurality of sub-pixels. The second electrode CE2 can be positioned on the micro-LED ED. As an example, the second electrode CE2 can be electrically connected to the pixel driving circuit PD through the plurality of contact electrodes CCE, without being limited thereto.

For example, the second electrode CE2 can be electrically connected to a cathode electrode 135 of the micro-LED ED and can transmit a cathode voltage from the pixel driving circuit PD to the micro-LED ED. The same cathode voltage can be applied to the second electrode CE2 of each of the plurality of sub-pixels. For example, the same voltage can be applied to the second electrode CE2 of each of the plurality of sub-pixels and the cathode electrode 135 of the micro-LED ED. Accordingly, the second electrode CE2 can be a common electrode, but the embodiments of the present disclosure are not limited thereto.

At least some of the plurality of sub-pixels can share the second electrode CE2. At least some of the second electrodes CE2 of the plurality of sub-pixels can be electrically connected to each other. As the same voltage is applied to the second electrodes CE2, the second electrodes CE2 of at least some sub-pixels can be shared. For example, the second electrodes CE2 of at least some of the plurality of pixels PX arranged in the same row can be connected to each other. For example, a single second electrode CE2 can be provided for the plurality of pixels PX. One second electrode CE2 can be provided for every n sub-pixels.

For example, some of the second electrodes CE2 of the plurality of sub-pixels can be spaced apart or separated from each other. For example, the second electrode CE2 connected to the pixels PX in an n^{th} row and the second electrode CE2 connected to the pixels PX in an (n+1)th row can be spaced apart or separated from each other. For example, the plurality of second electrodes CE2 can be spaced apart from each other with the plurality of communication wires NL, which extend in the row direction, interposed therebetween.

The plurality of second electrodes CE2 can be made of a transparent conductive material, but the embodiments of the present disclosure are not limited thereto. The plurality of second electrodes CE2 can be made of a transparent conductive material, allowing light emitted from the micro-LED ED to be directed upward through the second electrode CE2. For example, the second electrode CE2 can be made of a transparent conductive material such as indium tin oxide (ITO), indium zinc oxide (IZO), or indium gallium zinc oxide (IGZO), but the embodiments of the present disclosure are not limited thereto.

The plurality of contact electrodes CCE can be arranged on the substrate 110. For example, the plurality of contact electrodes CCE can be spaced apart from the plurality of banks BNK and the plurality of signal wires TL. Each of the plurality of second electrodes CE2 can overlap at least one contact electrode CCE. For example, one second electrode CE2 can overlap the plurality of contact electrodes CCE.

For example, the plurality of contact electrodes CCE can be electrically connected to the plurality of second electrodes CE2. The plurality of contact electrodes CCE can be positioned between the substrate 110 and the plurality of second electrodes CE2 and can transmit the cathode voltage from the pixel driving circuit PD to the second electrodes CE2.

For example, when using a micro-LED as the light emitting device ED, a plurality of micro-LEDs can be formed on a wafer and transferred to the substrate 110 of the display device 1000 to fabricate the display device 1000. In the process of transferring the plurality of micro-LEDs ED having a fine size from the wafer to the substrate 110, various defects can occur. For example, in some sub-pixels, a transfer failure can occur where the micro-LED ED is not transferred, and in some other sub-pixels, a defect can occur where the micro-LED ED is transferred to an incorrect position due to an alignment error. Additionally, even if the transfer process is normally performed, the transferred micro-LED ED itself can be defective. Therefore, in the transfer process of the plurality of micro-LEDs ED, in consideration of defects, a plurality of micro-LEDs ED that emit light of the same color can be transferred onto one sub-pixel. A lighting test can be performed on the plurality of micro-LEDs ED and only one micro-LED ED that is finally determined to be normal can be used. Embodiments are not limited thereto. As an example, at least some or all of the plurality of micro-LEDs ED transferred onto one sub-pixel can be used simultaneously, or sequentially, without being limited thereto. As an example, at least some or all of the plurality of micro-LEDs ED transferred onto one sub-pixel can be used simultaneously with the same or different brightness, without being limited thereto.

For example, a 1-1 micro-LED 130a and a 1-2 micro-LED 130b can be transferred together onto one pixel PX, and their defect states can be inspected. If both the 1-1 micro-LED 130a and the 1-2 micro-LED 130b are determined to be normal, only the 1-1 micro-LED 130a can be used and the 1-2 micro-LED 130b can remain unused. In another example, if, among the 1-1 micro-LED 130a and the 1-2 micro-LED 130b, only the 1-2 micro-LED 130b is determined to be normal, the 1-1 micro-LED 130a can remain unused and only the 1-2 micro-LED 130b can be used. Accordingly, even if a plurality of micro-LEDs ED that emit light of the same color are transferred onto one pixel PX, ultimately, only one of the micro-LEDs ED can be used.

Thus, in a pair of micro-LEDs ED, one can be a main (or primary) micro-LED ED, while the other can be a redundancy micro-LED ED. The redundancy micro-LED ED can be an extra micro-LED ED that is transferred in preparation for a defect in the main micro-LED ED. The redundant micro-LED can be used as a replacement in the event of a failure of the main micro-LED. Thus, by transferring both the main micro-LED ED and the redundancy micro-LED ED to one pixel PX, degradation in display quality due to defects in the main micro-LED ED or the redundancy micro-LED ED can be minimized.

For example, the 1-1 light emitting device 130a, the 2-1 light emitting device 140a, and the 3-1 light emitting device 150a transferred to one pixel PX can be used as the main light emitting device ED, and the 1-2 light emitting device 130b, the 2-2 light emitting device 140b, and the 3-2 light emitting device 150b can be used as the redundancy light emitting device ED.

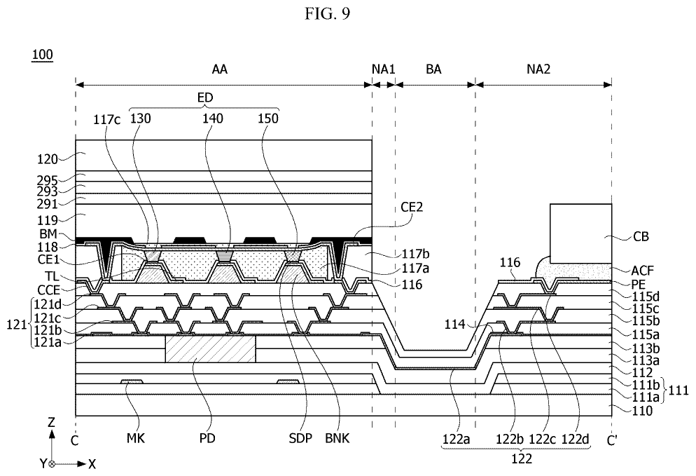

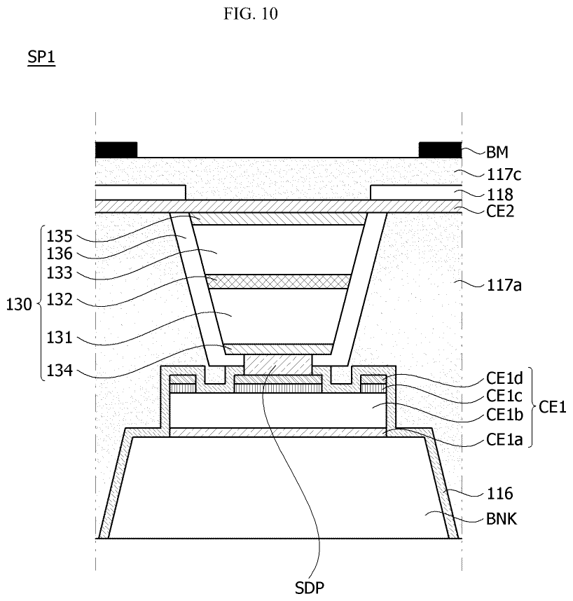

FIG. 9 is a cross-sectional view of a display device according to an example embodiment of the present disclosure. FIG. 10 is an enlarged cross-sectional view of a display device according to an example embodiment of the present disclosure. For example, FIG. 9 is a cross-sectional view of the display area AA, the first and second non-display areas NA1 and NA2, and the bending area BA.

Referring to FIG. 9, a buffer layer 111 can be disposed in the remaining area of the substrate 110 except for the bending area BA. The buffer layer 111 can include a first buffer layer 111a and a second buffer layer 111b. Embodiments are not limited thereto. As an example, the buffer layer 111 can include one single buffer layer, or three or more buffer layers. As an example, the buffer layer 111 can be omitted depending on the design.

The first buffer layer 111a and the second buffer layer 111b can be positioned in the display area AA, the first non-display area NA1, and the second non-display area NA2. The first buffer layer 111a and the second buffer layer 111b can reduce the permeation of moisture or impurities through the substrate 110. The first buffer layer 111a and the second buffer layer 111b can be made of an inorganic insulating material. For example, the first buffer layer 111a and the second buffer layer 111b can be configured as a single layer or multi-layer of silicon oxide (SiOx) or silicon nitride (SiNx), but the embodiments of the present disclosure are not limited thereto.

Referring to FIG. 12 to be described below, for example, the first buffer layer 111a and the second buffer layer 111b can be applied as the first stopper layer 111. For example, the first and second buffer layers 111a and 111b applied as the first stopper layer 111 can be disposed in the entire display area AA and the non-display area NA. The non-display area NA can include a first non-display area NA1, a bending area BA, and a second non-display area NA2. The first and second buffer layers 111a and 111b can be disposed in the first and second non-display areas NA1 and NA2, and can be removed from the bending area BA. And, as described with reference to FIG. 12, a first stopper opening 111c (see FIG. 12) can be formed in the first and second buffer layers 111a and 111b disposed in the first non-display area NA1.

For example, the first stopper layer 111 can be formed of a single layer or multiple layers of silicon oxide (SiOx) or silicon nitride (SiNx), which is an inorganic film material, but embodiments of the present disclosure are not limited thereto. For example, portions of the first buffer layer 111a and the second buffer layer 111b on the bending area BA can be removed. The upper surface of the substrate 110 located in the bending area BA can be exposed from the first buffer layer 111a and the second buffer layer 111b. By removing the first buffer layer 111a and the second buffer layer 111b made of the inorganic insulating material from the bending area BA, cracks in the first buffer layer 111a and the second buffer layer 111b that can occur during bending can be minimized.

As an example, a plurality of alignment keys MK can be arranged between the first buffer layer 111a and the second buffer layer 111b, without being limited thereto. The plurality of alignment keys MK can be configured to identify the position of the pixel driving circuit PD during the fabricating process of the display device 1000. For example, the plurality of alignment keys MK can be configured to align the position of the pixel driving circuit PD transferred onto an adhesive layer 112. In another example, the plurality of alignment keys MK can be omitted.

The adhesive layer 112 can be positioned on the second buffer layer 111b. The adhesive layer 112 can be positioned in the display area AA, the first non-display area NA1, the bending area BA, and the second non-display area NA2. In another example, at least a portion of the adhesive layer 112 can be removed from the non-display area NA that includes the bending area BA. For example, the adhesive layer 112 can be made of any one of an adhesive polymer, epoxy resin, UV-curable resin, a polyimide-based material, an acrylate-based material, a urethane-based material, or polydimethylsiloxane (PDMS), but the embodiments of the present disclosure are not limited thereto.

In the display area AA, the pixel driving circuit PD can be positioned on the adhesive layer 112. When the pixel driving circuit PD is implemented as a driving driver, the driving driver can be mounted on the adhesive layer 112 through a transfer process, but the embodiments of the present disclosure are not limited thereto.

A first protective layer 113a and a second protective layer 113b can be positioned on the top or side surfaces of the adhesive layer 112 and the pixel driving circuit PD. The first protective layer 113a and the second protective layer 113b can be positioned to surround the side surface of the pixel driving circuit PD, but the embodiments of the present disclosure are not limited thereto. For example, the second protective layer 113b can be positioned to cover at least a portion of the top surface of the pixel driving circuit PD. For example, at least one of the first protective layer 113a and the second protective layer 113b positioned in the bending area BA can be omitted, without being limited thereto.

For example, the first protective layer 113a can be entirely positioned over the display area AA and the non-display area NA, and the second protective layer 113b can be partially positioned over the display area AA, the first non-display area NA1, and the second non-display area NA2. For example, a portion of the second protective layer 113b in the bending area BA can be removed. However, the embodiments of the present disclosure are not limited thereto.

The first protective layer 113a and the second protective layer 113b can be formed of an organic insulating material, but the embodiments of the present disclosure are not limited thereto. For example, the first protective layer 113a and the second protective layer 113b can be formed of photoresist, polyimide (PI), or a photoacryl-based material, but the embodiments of the present disclosure are not limited thereto. For example, the first protective layer 113a and the second protective layer 113b can be an overcoating layer or an insulating layer, but the embodiments of the present disclosure are not limited thereto.

According to the example embodiments of the present disclosure, a plurality of first connection wires 121 can be arranged on the second protective layer 113b in the display area AA. The plurality of first connection wires 121 can be wires for electrically connecting the pixel driving circuit PD to other components. For example, the pixel driving circuit PD can be electrically connected to the plurality of signal wires TL, the plurality of contact electrodes CCE, and the like through the plurality of first connection wires 121. For example, the plurality of first connection wires 121 can include a 1-1 connection wire 121a, a 1-2 connection wire 121b, a 1-3 connection wire 121c, and a 1-4 connection wire 121d, and the 1-1 connection wire 121a, the 1-2 connection wire 121b, the 1-3 connection wire 121c, and the 1-4 connection wire 121d can be electrically connected to each other through contact holes formed in insulating layers between the connection wires, but the embodiments of the present disclosure are not limited thereto. As an example, the plurality of first connection wires 121 can include two or more connection wire electrically connected to each other through contact holes formed in insulating layers between the connection wires, without being limited thereto.

For example, a plurality of 1-1 connection wirings 121a can be disposed on the second protective layer 113b. A plurality of 1-1 connection wirings 121a can be electrically connected to the pixel driving circuit PD. A plurality of 1-1 connection wirings 121a can transfer voltages output from the pixel driving circuit PD to the first electrode CE1 or the second electrode CE2.

For example, the first and second protective layers 113a and 113b can be formed of an organic insulating material. For example, the first and second protective layers 113a and 113b can be formed of a photo resist, polyimide (PI), a photoacryl-based material, or the like, but embodiments of the present disclosure are not limited thereto. For example, the first protective layer 113a and the second protective layer 113b can be formed of the same material. Embodiments of the present disclosure are not limited thereto. For example, the first protective layer 113a and the second protective layer 113b can be insulating layers, but embodiments of the present disclosure are not limited thereto.

In addition, as will be described with reference to FIG. 12, the second stopper layer 114 can be disposed on the second protective layer 113b. For example, the second stopper layer 114 can be disposed in the entire display area AA and the non-display area NA. In addition, as will be described with reference to FIG. 12, a second stopper opening 114a of FIG. 12 can be formed in the second stopper layer 114 disposed in the first non-display area NA1. For example, the second stopper layer 114 can be formed of a single layer or multiple layers of silicon oxide (SiOx) or silicon nitride (SiNx), which is an inorganic film material, but embodiments of the present disclosure are not limited thereto.

A first organic insulating layer 115a can be disposed on the second stopper layer 114. The first organic insulating layer 115a can be formed of an organic insulating material, but embodiments of the present disclosure are not limited thereto. For example, the first organic insulating layer 115a can be formed of a photo resist, polyimide (PI), a photoacryl-based material, or the like, but embodiments of the present disclosure are not limited thereto.

In addition, a plurality of 1-2 connection wirings 121b can be disposed on the first organic insulating layer 115a. A plurality of 1-2 connection wirings 121b can be connected to or directly connected to the pixel driving circuit PD. For example, a portion of the 1-2 connection wiring 121b can be directly connected to the pixel driving circuit PD through a contact hole of the second stopper layer 114. Another portion of the 1-2 connection wiring 121b can be electrically connected to the 1-1 connection wiring 121a through a contact hole of the first stopper layer 114. However, embodiments of the present disclosure are not limited thereto. The voltage output from the pixel driving circuit PD can be transferred to the first electrode CE1 or the second electrode CE2 through connection wirings different from a plurality of 1-2 connection wirings 121b.

The second organic insulating layer 115b can be positioned on the plurality of 1-2 connection wires 121b. The second organic insulating layer 115b can be entirely positioned over the display area AA and the non-display area NA, but the embodiments of the present disclosure are not limited thereto. The second organic insulating layer 115b can be made of an organic insulating material, but the embodiments of the present disclosure are not limited thereto. For example, the first organic insulating layer 115a can be made of photoresist, polyimide (PI), or a photoacryl-based material, but the embodiments of the present disclosure are not limited thereto.

The plurality of 1-3 connection wires 121c can be positioned on the second organic insulating layer 115b. The plurality of 1-3 connection wires 121c can be electrically connected to the plurality of 1-2 connection wires 121b. For example, the 1-3 connection wire 121c can be electrically connected to the 1-2 connection wire 121b through a contact hole of the second organic insulating layer 115b.

A third organic insulating layer 115c can be positioned on the plurality of 1-3 connection wires 121c. The third organic insulating layer 115c can be positioned in a region excluding the bending area BA, but the embodiments of the present disclosure are not limited thereto. The third organic insulating layer 115c can be positioned in the display area AA, the first non-display area NA1, and the second non-display area NA2, but the embodiments of the present disclosure are not limited thereto. For example, a portion of the third organic insulating layer 115c positioned in the bending area BA can be removed. The third organic insulating layer 115c can be made of an organic insulating material, but the embodiments of the present disclosure are not limited thereto. For example, the third organic insulating layer 115b can be made of photoresist, polyimide (PI), or a photoacryl-based material, but the embodiments of the present disclosure are not limited thereto.

The plurality of first-fourth connection wires 121d can be positioned on the third organic insulating layer 115c. The plurality of first-fourth connection wires 121d can be electrically connected to the plurality of 1-3 connection wires 121c. For example, the first-fourth connection wire 121d can be electrically connected to the 1-3 connection wire 121c through a contact hole of the third insulating layer 115c.

A fourth organic insulating layer 115d can be disposed on a plurality of first to fourth connection wirings 121d. The fourth organic insulating layer 115d can be disposed in the remaining area except for the bending area BA, but embodiments of the present disclosure are not limited thereto. The fourth organic insulating layer 115d can be disposed in the display area AA, the first non-display area NA1, and the second non-display area NA2, but embodiments of the present disclosure are not limited thereto.

According to the example embodiments of the present disclosure, a plurality of second connection wires 122 can be positioned on the second protective layer 113b in the non-display area NA. The plurality of second connection wires 122 can be wires for transmitting a signal, which has been transmitted to the pad portion PAD from the flexible circuit board (or flexible film) CB and the printed circuit board 160 (see FIG. 1), to the pixel driving circuit PD of the display area AA. For example, the plurality of second connection wires 122 can be electrically connected to the plurality of pad electrodes PE to receive a signal from the flexible circuit board (or flexible film) CB and the printed circuit board 160.

For example, the plurality of second connection wires 122 can extend from the pad portion PAD toward the display area AA to transmit a signal to the wire of the display area AA. In this case, the plurality of second connection wires 122 can function as the link wires LL. The plurality of second connection wires 122 can include a 2-1 connection wire 122a, a 2-2 connection wire 122b, a 2-3 connection wire 122c, and a 2-4 connection wire 122d. Embodiments are not limited thereto. As an example, the plurality of second connection wires 122 can include two or more connection wires. As an example, the number of the plurality of second connection wires 122 can be equal to or different from the number of plurality of first connection wires 121. As an example, the plurality of second connection wires 122 can be disposed on the same level as the plurality of first connection wires 121, without being limited thereto.

A plurality of 2-1 connection wirings 122a can be disposed on the second protective layer 113b. A plurality of 2-1 connection wirings 122a can extend from the second non-display area NA2 to the bending area BA and the first non-display area NA1. A plurality of 2-1 connection wirings 122a can transmit signals transmitted from the flexible circuit board (or flexible film) CB and the printed circuit board to the pad portion PAD to the pixel driving circuit PD of the display area AA.

A plurality of 2-2 connection wirings 122b can be disposed on the second stopper layer 114 and the first organic insulating layer 115a. A plurality of 2-2 connection wirings 122b can be disposed in the second non-display area NA2. The 2-2 connection wiring 122b can be electrically connected to the 2-1 connection wiring 122a through a contact hole of the first stopper layer 114. Accordingly, the signal from the flexible circuit board (or flexible film) CB and the printed circuit board can be transmitted to the 2-1 connection wiring 122a through the 2-2 connection wiring 122b.

A 2-3 connection wiring 122c can be disposed on the second organic insulating layer 115b. The 2-3 connection wiring 122c can be disposed in the second non-display area NA2. The 2-3 connection wiring 122c can be electrically connected to the 2-2 connection wiring 122b through a contact hole of the second organic insulating layer 115b. Accordingly, the signal from the flexible circuit board (or flexible film) CB and the printed circuit board can be transmitted to the 2-1 connection wiring 122a through the 2-3 connection wiring 122c and the 2-2 connection wiring 122b.

A third organic insulating layer 115c can be disposed on the second organic insulating layer 115b and the 2-3 connection wiring 122c. Further, a 2-4 connection wiring 122d can be disposed on the third organic insulating layer 115c. The 2-4 connection wiring 122d can be disposed in the second non-display area NA2. The 2-4 connection wiring 122d can be electrically connected to the 2-3 connection wiring 122c through a contact hole of the third organic insulating layer 115c. Therefore, the signal from the flexible film FF and the printed circuit board can be transmitted to the 2-1 connection wiring 122a through the 2-4th connection wiring 122d, the 2-3th connection wiring 122c, and the 2-2 connection wiring 122b.

The plurality of first connection wires 121 and the plurality of second connection wires 122 can be formed of a highly flexible conductive material or any one of various conductive materials used in the display area AA.

For example, the second connection wiring 122 in which a part is disposed in the bending area BA can be made of a conductive material having excellent ductility, such as gold (Au), silver (Ag), or aluminum (Al), but embodiments of the present disclosure are not limited thereto. As an example, the plurality of first connection wires 121 and the plurality of second connection wires 122 can be formed of the same material or different materials. As an example, the plurality of 2-1 connection wirings 122a can be formed of a material the same as or different from the 1-1 connection lines 121a. As an example, the plurality of 2-1 connection wirings 122a can be formed of a material the same as or different from the others of the plurality of second connection wires 122, without being limited thereto.

For another example, the plurality of first connection wires 121 and the plurality of second connection wires 122 can be made of molybdenum (Mo), chromium (Cr), titanium (Ti), nickel (Ni), neodymium (Nd), copper (Cu), an alloy of silver (Ag) and magnesium (Mg), or other alloys thereof, but the embodiments of the present disclosure are not limited thereto.

The fourth organic insulating layer 115d can be positioned on the plurality of first connection wires 121 and the plurality of second connection wires 122. The fourth organic insulating layer 115d can be positioned in a region excluding the bending area BA, but the embodiments of the present disclosure are not limited thereto. The fourth organic insulating layer 115d can be positioned in the display area AA, the first non-display area NA1, and the second non-display area NA2. A portion of the fourth organic insulating layer 115d in the bending area BA can be removed. The fourth organic insulating layer 115d can be made of an organic insulating material, but the embodiments of the present disclosure are not limited thereto. For example, the fourth organic insulating layer 115d can be made of photoresist, polyimide (PI), or a photoacryl-based material, but the embodiments of the present disclosure are not limited thereto.

In the display area AA, the plurality of banks BNK can be positioned on the fourth organic insulating layer 115d. The plurality of banks BNK can respectively overlap the plurality of sub-pixels. One or more micro-LEDs ED that emit light of the same color can be positioned above each of the plurality of banks BNK.

A plurality of signal lines TL can be disposed on the fourth organic insulating layer 115d in the display area AA. A plurality of signal lines TL can be disposed in an area between a plurality of banks BNK. For example, a plurality of signal lines TL can be disposed adjacent to any one of a plurality of banks BNK.

The plurality of contact electrodes CCE can be positioned on the third insulating layer 115c or the fourth organic insulating layer 115d in the display area AA. The plurality of contact electrodes CCE can supply the cathode voltage from the pixel driving circuit PD to the second electrode CE2.

The first electrode CE1 can be positioned on the bank BNK. For example, the first electrode CE1 can extend from an adjacent signal wire TL toward the top of the bank BNK. The first electrode CE1 can be positioned on the top and side surfaces of the bank BNK. For example, the first electrode CE1 can extend from the signal wire TL on the top surface of the fourth organic insulating layer 115d to the side surface of the bank BNK and to the top surface of the bank BNK.

Referring to FIGS. 9 and 10, the first electrode CE1 can be composed of a plurality of conductive layers, without being limited thereto. For example, the first electrode CE1 can include a first conductive layer CE1a, a second conductive layer CE1b, a third conductive layer CE1c, and a fourth conductive layer CE1d, but the embodiments of the present disclosure are not limited thereto. As an example, the first electrode CE1 can be composed of one conductive layer or two or more conductive layers.

The first conductive layer CE1a can be positioned on the bank BNK. The second conductive layer CE1b can be positioned on the first conductive layer CE1a. The third conductive layer CE1c can be positioned on the second conductive layer CE1b. The fourth conductive layer CE1d can be positioned on the third conductive layer CE1c. For example, each of the first conductive layer CE1a, the second conductive layer CE1b, the third conductive layer CE1c, and the fourth conductive layer CE1d can be made of titanium (Ti), molybdenum (Mo), aluminum (Al), or titanium (Ti) and indium tin oxide (ITO), but the embodiments of the present disclosure are not limited thereto. As an example, the first conductive layer CE1a, the second conductive layer CE1b, the third conductive layer CE1c, and the fourth conductive layer CE1d can be made of the same material or different materials.

According to the example embodiments of the present disclosure, among the plurality of conductive layers constituting the first electrode CE1, some conductive layers with high reflection efficiency can be configured as an alignment key and/or a reflective plate for aligning the micro-LED ED.

For example, in order to configure the second conductive layer CE1b as a reflective plate, the third conductive layer CE1c and the fourth conductive layer CE1d covering the second conductive layer CE1b can be partially removed or etched. For example, portions of the third conductive layer CE1c and the fourth conductive layer CE1d positioned on the bank BNK can be removed or etched to expose the top surface of the second conductive layer CE1b. For example, in the third conductive layer CE1c and the fourth conductive layer CE1d, a central portion where the solder pattern SDP is positioned and a border portion (or edge portion) can be left, while the remaining portions can be removed. For example, the border portion (or edge portion) of each of the third conductive layer CE1c formed of titanium (Ti) and the fourth conductive layer CE1d formed of indium tin oxide (ITO) may not be etched. Accordingly, it is possible to prevent another conductive layer of the first electrode CE1 from being corroded by a tetramethylammonium hydroxide (TMAH) solution used in the masking process of the first electrode CE1. Embodiments are not limited thereto. As an example, any one or more of the first conductive layer CE1a, a second conductive layer CE1b, a third conductive layer CE1c, and a fourth conductive layer CE1d can be configured as a reflective plate. As an example, the conductive layer configured as a reflective plate can be exposed by the upper conductive layers, without being limited thereto.

According to the example embodiments of the present disclosure, the first conductive layer CE1a and the third conductive layer CE1c can be made of titanium (Ti) or molybdenum (Mo). The second conductive layer CE1b can be made of aluminum (Al). The fourth conductive layer CE1d can include a transparent conductive oxide layer, such as indium tin oxide (ITO) or indium zinc oxide (IZO), which has good adhesion to the solder pattern SDP and exhibits corrosion resistance and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned by a photolithography process and an etching process, but embodiments of the present disclosure are not limited thereto.

According to the example embodiments of the present disclosure, the signal wire TL, the contact electrode CCE, and the pad electrode PE positioned in the same layer as the first electrode CE1 can be composed of multiple layers of a conductive material, but the embodiments of the present disclosure are not limited thereto. For example, the signal line TL, the contact electrode CCE, and the pad electrode PE can be formed of a multilayer of indium tin oxide (ITO)/titanium (Ti)/aluminum (Al)/titanium (Ti), but embodiments of the present disclosure are not limited thereto.

According to the example embodiments of the present disclosure, the solder pattern SDP can be positioned on the first electrode CE1 in each of the plurality of sub-pixels. The solder pattern SDP can bond the micro-LED ED to the first electrode CE1 to electrically connect the first electrode CE1 to the micro-LED ED. For example, the first electrode CE1 and the anode electrode 134 of the micro-LED ED can be electrically connected to each other through eutectic bonding using the solder pattern SDP, but the embodiments of the present disclosure are not limited thereto. For example, when the solder pattern SDP be made of indium (In), and the anode electrode 134 of the micro-LED ED be made of gold (Au), the solder pattern SDP and the anode electrode 134 can be bonded by applying heat and pressure during the transfer process of the micro-LED ED. Through eutectic bonding, the micro-LED ED can be bonded to the solder pattern SDP and the first electrode CE1 without a separate adhesive material. For example, the solder pattern SDP can be made of indium (In), tin (Sn), or an alloy thereof, but the embodiments of the present disclosure are not limited thereto. For example, the solder pattern SDP can be a bonding pad or a joining pad, but the embodiments of the present disclosure are not limited thereto.

In addition, referring to FIG. 9, a third stopper layer 116 can be disposed on the fourth organic insulating layer 115d including the first electrode CE1 and a bank BNK. For example, the third stopper layer 116 can be disposed in the entire display area AA and the non-display area NA. As will be described with reference to FIG. 12, a first stopper opening 116a (see FIG. 12) can be formed in the third stopper layer 116 disposed in the first non-display area NA1. For example, the third stopper layer 116 can be formed of a single layer or multiple layers of silicon oxide (SiOx) or silicon nitride (SiNx), which is an inorganic film material, but embodiments of the present disclosure are not limited thereto.

According to the example embodiments of the present disclosure, the third stopper layer 116 serving as the passivation layer can be disposed on a plurality of signal lines TL, a plurality of first electrodes CE1, a plurality of contact electrodes CCE, and a third organic insulating layer 115c.

For example, the third stopper layer 116 can be positioned in the display area AA, the first non-display area NA1, and the second non-display area NA2. A portion of the third stopper layer 116 positioned in the bending area BA can be removed. In the second non-display area NA2, a portion of the passivation layer 116 covering the plurality of pad electrodes PE can be removed. Since the third stopper layer 116 is positioned to cover the remaining regions other than the bending area BA and the regions where the plurality of pad electrodes PE and the solder pattern SDP are positioned, penetration of moisture or impurities into the micro-LED ED can be reduced. For example, the third stopper layer 116 can be composed of a single layer or multiple layers of silicon oxide (SiOx) or silicon nitride (SiNx), but the embodiments of the present disclosure are not limited thereto.

In each of the plurality of sub-pixels, the micro-LED ED can be positioned on the solder pattern SDP. The first micro-LED 130 can be positioned in the first sub-pixel SP1. The second micro-LED 140 can be positioned in the second sub-pixel SP2. The third micro-LED 150 can be positioned in the third sub-pixel SP3.

The micro-LED ED can be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present disclosure are not limited thereto.

Referring to FIGS. 9 and 10, the first micro-LED 130 can include the anode electrode 134, a first semiconductor layer 131, an active layer 132, a second semiconductor layer 133, the cathode electrode 135, and an encapsulation film 136, but the embodiments of the present disclosure are not limited thereto. For example, the first micro-LED 130 may not include the encapsulation film 136.

A first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be implemented as a compound semiconductor of a group III-V or a group II-VI and can be doped with an impurity (or dopant), without being limited thereto. For example, one of the first semiconductor layer 131 and the second semiconductor layer 133 can be a semiconductor layer doped with an n-type impurity, while the other can be a semiconductor layer doped with a p-type impurity, but the embodiments of the present disclosure are not limited thereto. For example, at least one of the first semiconductor layer 131 and the second semiconductor layer 133 can be a layer in which an n-type or p-type impurity is doped into a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto.

The active layer 132 can be positioned between the first semiconductor layer 131 and the second semiconductor layer 133. The active layer 132 can emit light by receiving holes and electrons from the first semiconductor layer 131 and the second semiconductor layer 133. For example, the active layer 132 can be configured in one of a single well structure, a multi-well structure, a single quantum well structure, a multi-quantum well (MQW) structure, a quantum dot structure, and a quantum line structure, but the embodiments of the present disclosure are not limited thereto. For example, the active layer 132 can be made of indium gallium nitride (InGaN) or gallium nitride (GaN), but the embodiments of the present disclosure are not limited thereto.

For another example, the active layer 132 can include a well layer and a multi-quantum well (MQW) structure having a barrier layer having a band gap higher than that of the well layer. For example, the active layer 132 can include InGaN as a well layer and AlGaN layer as a barrier layer, but embodiments of the present disclosure are not limited thereto.

The anode electrode 134 can be disposed between the first semiconductor layer 131 and the solder pattern SDP. For example, the anode electrode 134 can electrically connect the first semiconductor layer 131 to the first electrode CE1. The anode voltage output from the pixel driving circuit PD can be applied to the first semiconductor layer 131 through the signal line TL, the first electrode CE1, and the anode electrode 134. For example, the anode electrode 134 can be formed of a conductive material capable of eutectic bonding with the solder pattern SDP. For example, the anode electrode 134 can be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present disclosure are not limited thereto.

The cathode electrode 135 can be positioned on the second semiconductor layer 133. For example, the cathode electrode 135 can electrically connect the second semiconductor layer 133 to the second electrode CE2. The cathode voltage outputted from the pixel driving circuit PD can be applied to the second semiconductor layer 133 through the contact electrode CCE, the second electrode CE2, and the cathode electrode 135. The cathode electrode 135 can be formed of a transparent conductive material such that light emitted from the micro-LED ED can be directed toward an upper side of the micro-LED ED, but the embodiments of the present disclosure are not limited thereto. For example, the cathode electrode 135 can be formed of a material such as indium tin oxide (ITO), indium zinc oxide (IZO), or indium gallium zinc oxide (IGZO), but the embodiments of the present disclosure are not limited thereto.

The encapsulation film 136 can be positioned on at least portions of each of the first semiconductor layer 131, the active layer 132, the second semiconductor layer 133, the anode electrode 134, and the cathode electrode 135. For example, the encapsulation film 136 can surround at least portions of each of the first semiconductor layer 131, the active layer 132, the second semiconductor layer 133, the anode electrode 134, and the cathode electrode 135.

For example, the encapsulation film 136 can be disposed on at least a portion of each of the anode electrode 134 and the cathode electrode 135, for example, on the edge portion (or periphery portion or one side) of the anode electrode 134 and the edge portion (or periphery portion or one side) of the cathode electrode 135. At least a portion of the anode electrode 134 can be exposed from the encapsulation film 136 to connect the anode electrode 134 and the solder pattern SDP. For example, at least a portion of the cathode electrode 135 can be exposed from the encapsulation film 136 to connect the cathode electrode 135 and the second electrode CE2. For example, the encapsulation film 136 can be formed of an insulating material such as silicon nitride (SiNx) or silicon oxide (SiOx), but embodiments of the present disclosure are not limited thereto.

As another example, the encapsulation film 136 can have a structure in which a reflective material is dispersed in a resin layer, but embodiments of the present disclosure are not limited thereto. For example, the encapsulation film 136 can be manufactured as a reflector having various structures, but embodiments of the present disclosure are not limited thereto. Light emitted from the active layer 132 by the encapsulation film 136 can be reflected upward to improve light extraction efficiency. For example, the encapsulation film 136 can be a reflective layer, but embodiments of the present disclosure are not limited thereto.

Although the light emitting device ED has been described as a vertical type structure according to the example embodiments of the present disclosure, embodiments of the present disclosure are not limited thereto. For example, the light emitting device ED can have a lateral STA structure or a flip chip STA structure.

Although the first light emitting device 130 has been described with reference to FIG. 10, the second light emitting device 140 and the third light emitting device 150 can have substantially the same structure as the first light emitting device 130. For example, the second light emitting device 140 and the third light emitting device 150 can be substantially the same as the first semiconductor layer 131, the active layer 132, the second semiconductor layer 133, the anode electrode 134, the cathode electrode 135, and the encapsulation film 136.

According to the example embodiments of the present disclosure, a first optical layer 117a can be positioned on the third stopper layer 116 to surround the plurality of micro-LEDs ED in the display area AA. For example, the first optical layer 117a can be positioned to cover the plurality of micro-LEDs ED and the bank BNK in regions of the plurality of sub-pixels. For example, the first optical layer 117a can cover the bank BNK, a portion of the passivation layer 116 and the spaces between the plurality of micro-LEDs ED. The first optical layer 117a can be positioned between the plurality of banks BNK and between the plurality of micro-LEDs ED included in one pixel PX, or can cover those spaces. For example, the first optical layer 117a can extend in a first direction X and can be separated in a second direction Y. For example, the first optical layer 117a can be positioned between the passivation layer 116 and the second electrode CE2 to surround the side portions of the micro-LED ED and the bank BNK, but the embodiments of the present disclosure are not limited thereto. For example, the first optical layer 117a can be a diffusion layer, a sidewall diffusion layer, or the like, but the embodiments of the present disclosure are not limited thereto.

The first optical layer 117a can be formed of an organic insulating material in which fine particles are dispersed, but the embodiments of the present disclosure are not limited thereto. For example, the first optical layer 117a can be made of siloxane in which fine metal particles such as titanium dioxide (TiO₂) particles are dispersed, but the embodiments of the present disclosure are not limited thereto. Light from the plurality of micro-LEDs ED can be scattered by the fine particles dispersed in the first optical layer 117a and emitted to the outside of the display device 1000. Accordingly, the first optical layer 117a can improve the light extraction efficiency of the light emitted from the plurality of micro-LEDs ED.

For example, the first optical layer 117a can be positioned in each of the plurality of pixels PX, or can be commonly positioned in some of the pixels PX arranged in the same row, but the embodiments of the present disclosure are not limited thereto. For example, the first optical layer 117a can be positioned in each of the plurality of pixels PX, or a single first optical layer 117a can be shared by the plurality of pixels PX. In another example, each of the plurality of sub-pixels can separately include the first optical layer 117a, but the embodiments of the present disclosure are not limited thereto.

According to the example embodiments of the present disclosure, the second optical layer 117b can be disposed on the third stopper layer 116 in the display area AA. For example, the second optical layer 117b can be disposed to surround the first optical layer 117a. For example, the second optical layer 117b can be in contact with the side surface of the first optical layer 117a. For example, the second optical layer 117b can be disposed in an area between a plurality of pixels PX. However, embodiments of the present disclosure are not limited thereto, for example, the second optical layer 117b can be a diffusion layer, a diffusion layer window, a window diffusion layer, or the like, but embodiments of the present disclosure are not limited thereto.

The second optical layer 117b can be formed of an organic insulating material, but embodiments of the present disclosure are not limited thereto. The second optical layer 117b can be formed of the same material as the first optical layer 117a, but embodiments of the present disclosure are not limited thereto. For example, the first optical layer 117a can include fine particles, and the second optical layer 117b may not include fine particles. For example, the second optical layer 117b can be formed of siloxane, but embodiments of the present disclosure are not limited thereto.

For example, the thickness of the first optical layer 117a can be less than that of the second optical layer 117b, but embodiments of the present disclosure are not limited thereto. Accordingly, when viewed in a plan view, the region in which the first optical layer 117a is disposed can include a concave portion recessed inwardly from the upper surface of the second optical layer 117b.

According to the example embodiments of the present disclosure, the second electrode CE2 can be disposed on the first optical layer 117a and the second optical layer 117b. For example, the second electrode CE2 can be electrically connected to a plurality of contact electrodes CCE through a contact hole of the second optical layer 117b. For example, the second electrode CE2 can be disposed on a plurality of light emitting devices ED. For example, the second electrode CE2 can include a transparent conductive oxide such as indium tin oxide (ITO) or indium zinc oxide (IZO), but embodiments of the present disclosure are not limited thereto. For example, the second electrode CE2 can be disposed to be in contact with the cathode electrode 135. For example, the second electrode CE2 can overlap the first optical layer 117a. For example, the outer plane of the first optical layer 117a can be covered. The second electrode CE2 can continuously extend in the first direction X of the substrate 110.

Accordingly, the second electrode CE2 can be commonly connected to a plurality of pixels PX arranged in the first direction X. For example, the second electrode CE2 can be commonly connected to a plurality of pixels PX.

According to the example embodiments of the present disclosure, the second electrode CE2 can continuously extend on the first optical layer 117a, the second optical layer 117b, and the light emitting device ED. The region in which the first optical layer 117a is disposed can include a concave portion recessed inwardly from the upper surface of the second optical layer 117b. Accordingly, since the first portion of the second electrode CE2 disposed on the first optical layer 117a is disposed along the concave portion, the first portion can be disposed at a lower position than the second portion of the second electrode CE2 disposed on the second optical layer 117b.

In addition, the fourth stopper layer 118 can be disposed on the second electrode CE2 and the first optical layer 117a. For example, the fourth stopper layer 118 can be disposed in the entire display area AA and the non-display area NA. As will be described with reference to FIG. 12, the fourth stopper opening 118a of FIG. 12 can be formed in the fourth stopper layer 118 disposed in the first non-display area NA1. For example, the fourth stopper layer 118 can be formed of a single layer or multiple layers of silicon oxide (SiOx) or silicon nitride (SiNx), which is an inorganic film material, but embodiments of the present disclosure are not limited thereto.

The third optical layer 117c can be disposed to overlap a plurality of light emitting devices ED and the first optical layer 117a. Since the third optical layer 117c is disposed on the second electrode CE2 and a plurality of light emitting devices ED, a stain (Mura) that can occur in some of a plurality of light emitting devices ED can be improved. For example, when a plurality of light emitting devices ED are transferred onto the substrate 110 of the display device 1000, a region in which a gap between a plurality of light emitting devices ED is not uniform due to a process variation or the like can occur. When the spacing between the plurality of light emitting devices ED is non-uniform, the light emitting area of each of the plurality of light emitting devices ED can be non-uniformly disposed, and thus a stain (Mura) can be visually recognized by the user.

Accordingly, since the third optical layer 117c configured to uniformly diffuse light on the plurality of light emitting devices ED is configured, light emitted from some light emitting devices ED can be reduced from being visually recognized like a stain.

Therefore, since the light emitted from the plurality of light emitting devices ED is evenly diffused by the third optical layer 117c and extracted to the outside of the display device 1000, the luminance uniformity of the display device 1000 can be improved.

The third optical layer 117c can be formed of an organic insulating material in which fine particles are dispersed, but embodiments of the present disclosure are not limited thereto. For example, the third optical layer 117c can be formed of siloxane in which fine metal particles such as titanium dioxide (TiO₂) particles are dispersed, but embodiments of the present disclosure are not limited thereto. For example, the third optical layer 117c can be formed of the same material as the first optical layer 117a, but embodiments of the present disclosure are not limited thereto. For example, the third optical layer 117c can be a diffusion layer, an upper diffusion layer, or the like, but embodiments of the present disclosure are not limited thereto.

According to the example embodiments of the present disclosure, light from a plurality of light emitting devices ED can be scattered by fine particles dispersed in the third optical layer 117c and emitted to the outside of the display device 1000. The third optical layer 117c can evenly mix light emitted from a plurality of light emitting devices ED to further improve luminance uniformity of the display device 1000. In addition, light extraction efficiency of the display device 1000 can be improved by light scattered from a plurality of fine particles, and thus the display device 1000 can be driven at a low power.

In the display area AA, a black matrix BM can be disposed on the second electrode CE2, the first optical layer 117a, the second optical layer 117b, the third optical layer 117c, and the fourth stopper layer 118. For example, the black matrix BM can fill a contact hole of the second optical layer 117b. Since the black matrix BM is configured to cover the display area AA, color mixture and reflection of external light of a plurality of sub-pixels can be reduced. For example, since the black matrix BM is disposed within a contact hole in which the second electrode CE2 is connected with the contact electrode CCE, light leakage between a plurality of neighboring sub-pixels can be prevented.

For example, the black matrix BM can be formed of an opaque material, but embodiments of the present disclosure are not limited thereto. For example, the black matrix BM can be an organic insulating material to which a black pigment or a black dye is added, but embodiments of the present disclosure are not limited thereto.

In the display area AA, a cover layer 119 of FIG. 12 can be disposed on the black matrix BM. The cover layer 119 can protect an element under the fourth stopper layer 118. For example, the cover layer 119 can be formed of an organic insulating material, but embodiments of the present disclosure are not limited thereto. For example, the cover layer 119 can be formed of a photo resist, polyimide (PI), a photo acryl-based material, or the like, but embodiments of the present disclosure are not limited thereto. For example, the cover layer 119 can be an overcoating layer, an insulating layer, or the like, but embodiments of the present disclosure are not limited thereto.

As shown in FIG. 1, the polarizing layer 293 can be disposed on the cover layer 119 via the first adhesive layer 291. The cover member 120 can be disposed on the polarizing layer 293 via the second adhesive layer 295. For example, the first adhesive layer 291 and the second adhesive layer 295 can include an optically clear adhesive (OCA), an optically clear resin (OCR), a pressure sensitive adhesive (PSA) or the like, but embodiments of the present disclosure are not limited thereto.

According to the example embodiments of the present disclosure, a plurality of pad electrodes PE can be disposed on the fourth organic insulating layer 115d in the second non-display area NA2. For example, at least portions of a plurality of pad electrodes PE can be exposed from the passivation layer 116. For example, a plurality of pad electrodes PE can be electrically connected to the 2-4th connection wiring 122d through a contact hole of the fourth organic insulating layer 115d.

An adhesive layer ACF can be disposed on a plurality of pad electrodes PE. The adhesive layer ACF can be an adhesive layer in which conductive balls are dispersed in an insulating material, but embodiments of the present disclosure are not limited thereto. When heat or pressure is applied to the adhesive layer ACF, the conductive balls can be electrically connected to a portion where heat or pressure is applied to have conductive characteristics. An adhesive layer ACF can be disposed between a plurality of pad electrodes PE and a flexible circuit board (or a flexible film) CB to attach or bond a flexible circuit board (or a flexible film) CB to a plurality of pad electrodes PE. For example, the adhesive layer ACF can be an anisotropic conductive film (ACF), but embodiments of the present disclosure are not limited thereto.

A flexible circuit board (or a flexible film) CB can be disposed on the adhesive layer ACF. The flexible circuit board (or a flexible film) CB can be electrically connected to a plurality of pad electrodes PE through an adhesive layer ACF. Thus, the signals output from the flexible circuit board (or flexible film) CB and the printed circuit board can be transmitted to the pixel driving circuit PD of the display area AA through a plurality of pad electrodes PE, a 2-4 connection wiring 122d, a 2-3 connection wiring 122c, a 2-2 connection wiring 122b, and a 2-1 connection wiring 122a.

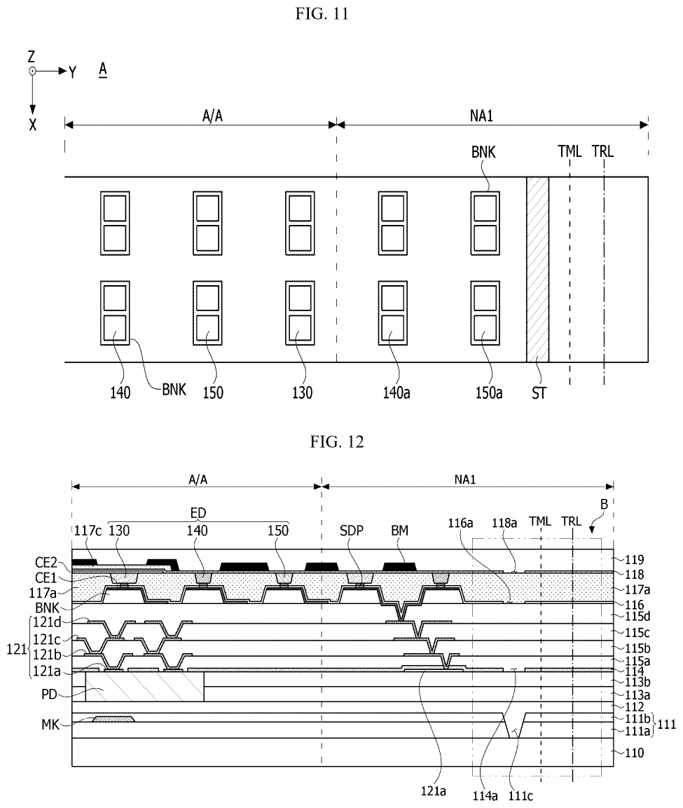

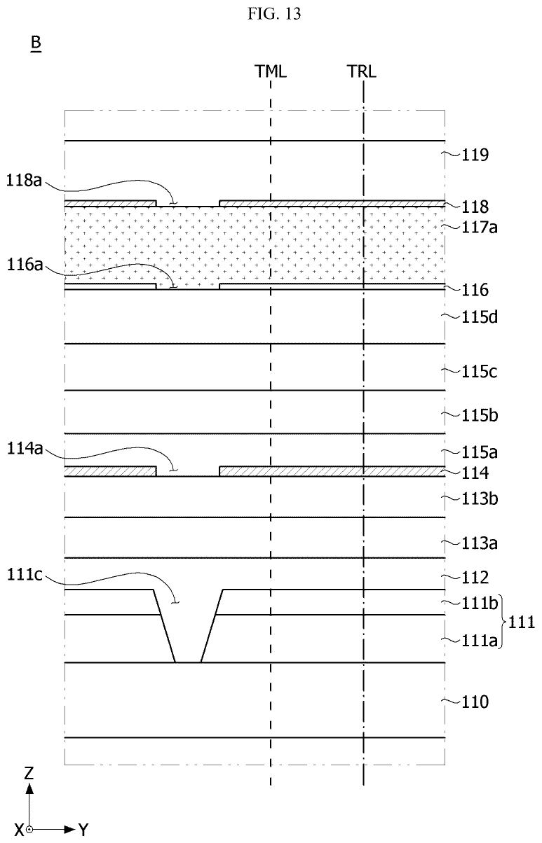

FIG. 11 is an enlarged plan view of a portion A of FIG. 3 of a display device according to one example embodiment of the present disclosure. FIG. 12 is a cross-sectional view of the display device according to one example embodiment of the present disclosure. FIG. 13 is an enlarged cross-sectional view of portion B in FIG. 12.

Referring to FIGS. 11 to 13, the display device according to one example embodiment of the present disclosure can include a display region AA and a non-display region NA which surrounds the display region AA or is present near the display region AA.

The non-display region NA can include a first non-display region NA1, a bending region BA, and a second non-display region NA2. For example, the display region AA can be configured in various shapes depending on the design of a display device (1000 in FIG. 12). For example, the display region AA can be configured in a rectangular shape whose four corners are formed in a round shape, but the embodiments of the present disclosure are not limited thereto. For another example, the display region AA can be configured in a rectangular shape whose four corners are formed in a right-angled shape, a circular shape, or the like, but the embodiments of the present disclosure are not limited thereto.

The first non-display region NA1 can have a form surrounding the display region AA. The bending region BA can be configured in a non-display region NA extending from the display region AA. Further, the second non-display region NA2 can include a non-display region extending from the bending region BA and surrounding the region where a pad portion PAD is located. However, the present disclosure is not limited thereto.

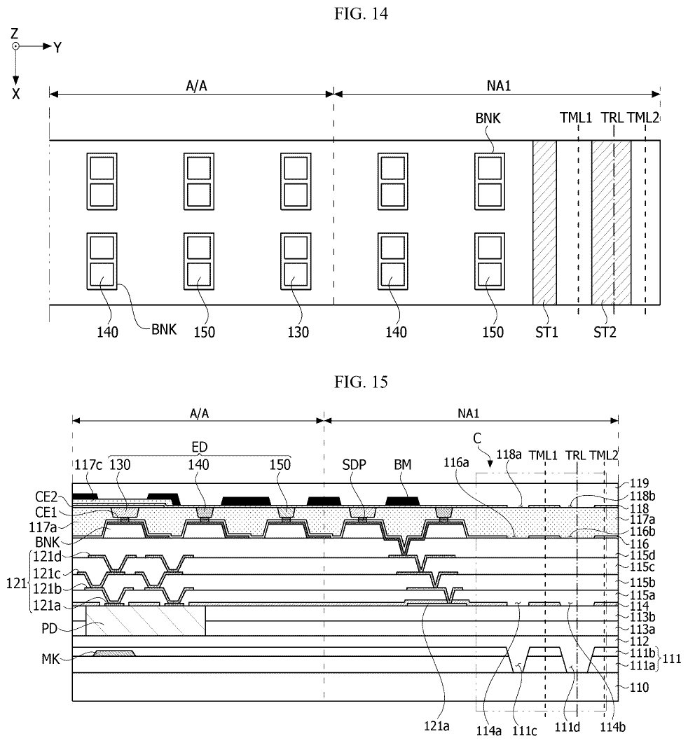

Further, a trimming line TRL can be configured in the first non-display region NA1 surrounding the display region AA and the second non-display region NA2 surrounding the bending region BA and the pad portion PAD. Further, a trimming margin line TML can be configured inside and outside the trimming line TRL to secure a cutting line margin of the trimming line TRL during laser trimming. A trimming margin line (TML2 in FIG. 14) defined outside the trimming line TRL can be removed during laser trimming. Trimming can be the laser trimming, but the embodiments of the present disclosure are not limited thereto.

Referring to FIG. 11, when viewed in a plan view, a closed loop-shaped crack stopper ST can be disposed in a region between the trimming margin line TML of the first non-display region NA1 surrounding the display region AA and the dummy light-emitting elements. Further, the crack stopper ST can be configured in a region between the plurality of dummy light-emitting elements disposed in the first non-display region NA1 and the trimming margin line TML.

The crack stopper ST1 can be formed on a plurality of inorganic films disposed in the display region AA and the first non-display region NA1. The crack stopper ST can be configured by forming a closed loop-shaped opening when viewed in a plan view on the plurality of inorganic films located in the first non-display region NA1. For example, an opening-shaped crack stopper ST can mean that the plurality of inorganic films are separated by the crack stopper ST. Possibility that cracks occurring through the inorganic film on one side, for example, a portion of the inorganic film close to the trimming margin line TML, propagate to the other side, for example, a portion of the inorganic film in the display region AA can be blocked in advance by the opening-shaped crack stopper ST formed in each inorganic film.

Accordingly, cracks occurring in the inorganic film inside the trimming margin line TML can be reduced or prevented from propagating to the display region AA in advance by the opening, for example, the crack stopper ST.

Referring FIGS. 12 and 13, a plurality of stopper layers 111, 114, 116, and 118 can be disposed in the display region AA and the first non-display region NA1. First to fourth stopper openings 111c, 114a, 116a, and 118a that serve as crack stoppers can be respectively formed in the plurality of stopper layers (111, 114, 116, and 118 in FIG. 12) located in the first non-display region NA1. Further, the first to fourth stopper openings 111c, 114a, 116a, and 118a may not be formed in the plurality of stopper layers 111, 114, 116, and 118 located in the second non-display region NA2 provided with the bending region BA and the pad portion PAD. However, the present disclosure is not limited thereto. The first stopper 111 can include a stacked structure of first and second buffer layers 111a and 111b. However, the present disclosure is not limited thereto.

The first to fourth stopper openings 111c, 114a, 116a, and 118a can block cracks occurring in the first non-display region NA1 from propagating to the display region AA during laser trimming. The first to fourth stopper openings 111c, 114a, 116a, and 118a respectively formed in the first to fourth stopper layers 111, 114, 116, and 118 can be configured in an open shape in which layers under the stopper openings are exposed, but the present disclosure is not limited thereto.

The first to fourth stopper openings 111c, 114a, 116a, and 118a can be formed in a closed loop shape surrounding the display region AA in the first non-display region NA1 as shown in FIG. 3 when viewed in a plan view. However, the closed loop shape can be formed in various shapes such as a line shape, a zigzag shape, and the like when viewed in a plan view. However, the present disclosure is not necessarily limited thereto. For example, each of the first to fourth stopper layers 111, 114, 116, and 118 can have a shape which is independently spaced or separated based on each of the first to fourth stopper openings 111c, 114a, 116a, and 118a.

Since each of the first to fourth stopper layers 111, 114, 116, and 118 is independently spaced or separated by the first to fourth stopper openings 111c, 114a, 116a, and 118a, even when cracks occur in the first to fourth stopper layers 111, 114, 116, and 118 in the first non-display region NA1, the cracks may not propagate to the display region AA. When each of the first to fourth stopper openings 111c, 114a, 116a, and 118a is not integrally formed in the closed loop shape in the first non-display region NA1, but is formed only in a partial region of the first non-display region NA1, cracks occurring during laser trimming can propagate to the display region AA through a portion of the stopper layer where the stopper opening is not formed.

The first to fourth stopper openings 111c, 114a, 116a, and 118a can be formed inside the trimming margin line TML in the first non-display region NA1, for example, in the first non-display region NA1 facing the display region AA.

For example, the first buffer layer 111a and the second buffer layer 111b can be configured as the first stopper layer 111. For example, the first and second buffer layers 111a and 111b applied as the first stopper layer 111 can be entirely disposed in the display region AA and the non-display region NA. For example, the first stopper layer 111 can be composed of a single layer or multiple layers of silicon oxide (SiOₓ) or silicon nitride (SiNₓ) which is an inorganic film material, but the embodiments of the present disclosure are not limited thereto. The first stopper opening 111c can be formed in a portion located inside the trimming margin line TML in the first stopper layer 111 located in the first non-display region NA1. The first stopper opening 111c can be formed as a portion of the first stopper layer 111 is open. Further, the first stopper opening 111c can be formed in a closed loop shape surrounding the display region AA in the first non-display region NA1 when viewed from above, but the present disclosure is not limited thereto.

In addition, a first organic insulating layer 112 and first and second protective layers 113a and 113b can be disposed on the first stopper layer 111. The second stopper layer 114 can be disposed on the first protective layer 113b. For example, the second stopper layer 114 can be entirely disposed in the display region AA and the non-display region NA. The second stopper layer 114 can be disposed on a pixel driving circuit PD. For example, the second stopper layer 114 can be composed of a single layer or multiple layers of silicon oxide (SiOₓ) or silicon nitride (SiNₓ) which is an inorganic film material, but the embodiments of the present disclosure are not limited thereto. For example, the second stopper opening 114a can be formed in a portion located inside the trimming margin line TML in the second stopper layer 114 located in the first non-display region NA1. The second stopper opening 114a can be formed as a portion of the second stopper layer 114 is open. For example, the second stopper opening 114a can be formed in a closed loop shape surrounding the display region AA in the first non-display region NA1 when viewed from above, but the present disclosure is not limited thereto.

A first organic insulating layer 115a can be disposed on the second stopper layer 114. The first organic insulating layer 115a can be composed of an organic insulating material, but the embodiments of the present disclosure are not limited thereto. For example, the first organic insulating layer 115a can be composed of a photoresist, a polyimide (PI)-based material, a photo acrylic-based material, or the like, but the embodiments of the present disclosure are not limited thereto.

A plurality of 1-2 connection lines 121b can be disposed on the first organic insulating layer 115a. The plurality of 1-2 connection lines 121b can be connected to or directly connected to the pixel driving circuit PD. For example, some of the 1-2 connection lines 121b can be directly connected to the pixel driving circuit PD through contact holes of the second stopper layer 114. Other 1-2 connection lines 121b can be electrically connected to 1-1 connection lines 121a through contact holes of the second stopper layer 114.

A second organic insulating layer 115b can be disposed on the plurality of 1-2 connection lines 121b. The second organic insulating layer 115b can be entirely disposed in the display region AA and the non-display region NA, but the embodiments of the present disclosure are not limited thereto.

A plurality of 1-3 connection lines 121c can be disposed on the second organic insulating layer 115b. The plurality of 1-3 connection lines 121c can be electrically connected to the plurality of 1-2 connection lines 121b. For example, the 1-3 connection lines 121c can be electrically connected to the 1-2 connection lines 121b through contact holes of the second organic insulating layer 115b.

A third organic insulating layer 115c can be disposed on the plurality of 1-3 connection lines 121c. The third organic insulating layer 115c can be disposed in the remaining regions excluding the bending region BA, but the embodiments of the present disclosure are not limited thereto.

A plurality of 1-4 connection lines 121d can be disposed on the third organic insulating layer 115c. The plurality of 1-4 connection lines 121d can be electrically connected to the plurality of 1-3 connection lines 121c. For example, the 1-4 connection lines 121d can be electrically connected to the 1-3 connection lines 121c through contact holes of the third organic insulating layer 115c.

A fourth organic insulating layer 115d can be disposed on the plurality of 1-4 connection lines 121d. The fourth organic insulating layer 115d can be disposed in the remaining regions excluding the bending region BA, but the embodiments of the present disclosure are not limited thereto. The fourth organic insulating layer 115d can be disposed in the display region AA, the first non-display region NA1, and the second non-display region NA2, but the embodiments of the present disclosure are not limited thereto.

The third stopper layer 116 can be disposed on the fourth organic insulating layer 115d including a first electrode CE1 and a bank BNK. For example, the third stopper layer 116 can be entirely disposed in the display region AA and the non-display region NA. For example, the third stopper layer 116 can be composed of a single layer or multiple layers of silicon oxide (SiOₓ) or silicon nitride (SiNₓ) which is an inorganic film material, but the embodiments of the present disclosure are not limited thereto. For example, the third stopper opening 116a can be formed in a portion located inside the trimming margin line TML in the third stopper layer 116 located in the first non-display region NA1. The third stopper opening 116a can be formed as a portion of the third stopper layer 116 is open. The third stopper opening 116a can be formed in a closed loop shape surrounding the display region AA when viewed in a plan view, but the present disclosure is not limited thereto.

According to the example embodiments of the present disclosure, the third stopper layer 116 can be disposed on a plurality of signal lines TL, a plurality of first electrodes CE1, a plurality of contact electrodes CCE, and the third insulating layer 115c. For example, the third stopper layer 116 can be disposed in the display region AA, the first non-display region NA1, and the second non-display region NA2. The third stopper layer 116 can be a passivation layer, but the embodiments of the present disclosure are not limited thereto.

The third stopper layer 116 can be disposed to cover the remaining regions excluding regions where the bending region BA, a plurality of pad electrodes PE, and a solder pattern SDP are disposed. Accordingly, the penetration of moisture or impurities into the light-emitting element ED can be reduced. For example, the third stopper layer 116 can be composed of a single layer or multiple layers of silicon oxide (SiOₓ) or silicon nitride (SiNₓ) which is an inorganic film material, but the embodiments of the present disclosure are not limited thereto. For example, the third stopper layer 116 can be a protective layer or an insulating layer, but the embodiments of the present disclosure are not limited thereto. For example, the third stopper layer 116 can include a hole which exposes the solder pattern SDP.

The fourth stopper layer 118 can be disposed on a second electrode CE2 and a first optical layer 117a. For example, the fourth stopper layer 118 can be entirely disposed in the display region AA and the non-display region NA. For example, the fourth stopper layer 118 can be composed of a single layer or multiple layers of silicon oxide (SiOₓ) or silicon nitride (SiNₓ) which is an inorganic film material, but the embodiments of the present disclosure are not limited thereto. For example, the fourth stopper opening 118a can be formed in a portion located inside the trimming margin line TML in the fourth stopper layer 118 located in the first non-display region NA1. The fourth stopper opening 118a can be formed as a portion of the fourth stopper layer 118 is open. The fourth stopper opening 118a can be formed in a closed loop shape surrounding the display region AA when viewed in a plan view, but the present disclosure is not limited thereto. Further, a third optical layer 117c can be disposed on the fourth stopper layer 118 on the second electrode CE2.

According to one example embodiment of the present disclosure, as shown in FIGS. 11 to 13, the first to fourth stopper layers 111, 114, 116, and 118 can be disposed in the display region AA, the first non-display region NA1, and the second non-display region NA2. Further, the closed loop-shaped first to fourth stopper openings 111c, 114a, 116a, and 118a when viewed from above can be respectively formed in portions of the first to fourth stopper layers 111, 114, 116, and 118 disposed in the first non-display region NA1.

In addition, the first to fourth stopper openings 111c, 114a, 116a, and 118a can be respectively formed in the first to fourth stopper layers 111, 114, 116, and 118 in the first non-display region NA1 located between the trimming margin line TML in the first non-display region NA1 and the display region AA. In addition, the first to fourth stopper openings 111c, 114a, 116a, and 118a can be formed in a collinear line in a vertical direction with respect to the substrate. As an example, the first to fourth stopper openings 111c, 114a, 116a, and 118a can at least partially overlap each other in a vertical direction with respect to the substrate, or may not overlap each other in the vertical direction. As an example, at least one of the first to fourth stopper openings 111c, 114a, 116a, and 118a can be omitted depending on the design, without being limited thereto. As an example, edges of at least some or all of the first to fourth stopper openings 111c, 114a, 116a, and 118a can overlap each other in a vertical direction with respect to the substrate, without being limited thereto. As an example, the first to fourth stopper openings 111c, 114a, 116a, and 118a can have the same size or different sizes.

According to one example embodiment of the present disclosure, even when the cracks occur in the first to fourth stopper layers 111, 114, 116, and 118 located in the first non-display region NA1 during laser trimming on the trimming line TRL, since the cracks may not propagate to the display region AA by the first to fourth stopper openings 111c, 114a, 116a, and 118a, the reliability and yield of the display device can be enhanced.

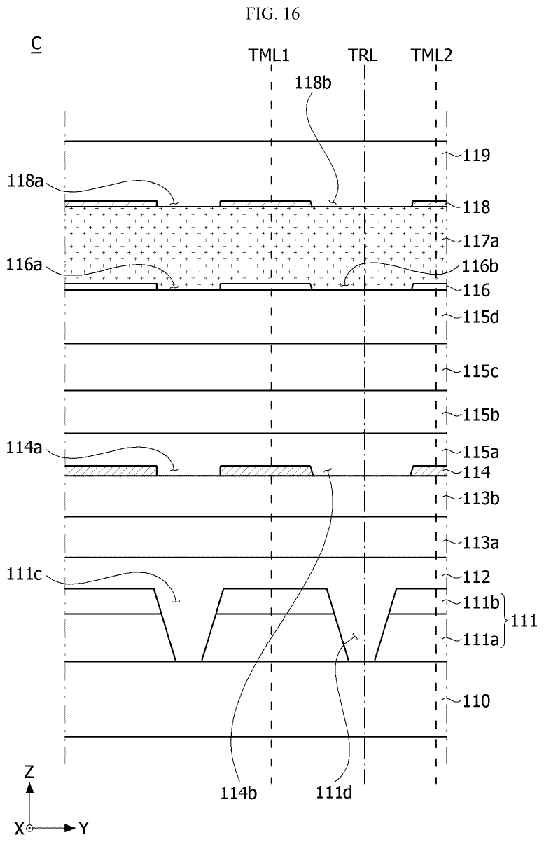

FIG. 14 is a plan view of a display device according to another example embodiment of the present disclosure. FIG. 15 is a cross-sectional view of the display device according to another example embodiment of the present disclosure. FIG. 16 is an enlarged cross-sectional view of portion C in FIG. 15.

FIGS. 14 to 16 show the display device according to another example embodiment of the present disclosure, and first to fourth auxiliary stopper openings 111d, 114b, 116b, and 118b can be additionally formed along with first to fourth stopper openings 111d, 114a, 116a, and 118a. Since the display device according to another example embodiment of the present disclosure is formed of substantially the same components as the display device according to one example embodiment of the present disclosure, the description will focus on a case in which the first to fourth auxiliary stopper openings 111d, 114b, 116b, and 118b are additionally formed.

According to another example embodiment of the present disclosure, a trimming line TRL and a trimming margin line TML can be disposed in a first non-display region NA1. The trimming line TRL and the trimming margin line TML can be formed to surround a display region AA in the first non-display region NA1.

Further, the trimming margin line TML can include a first trimming margin line TML1 and a second trimming margin line TML2 disposed inside and outside the trimming line TRL at a certain interval. Here, the first trimming margin line TML1 can be defined in the first non-display region NA1 located inside the trimming line TRL facing the display region AA. Further, the second trimming margin line TML2 can be configured in the first non-display region NA1 located outside the trimming line TRL. The second trimming margin line TML2 can be removed during laser trimming.

Referring to FIG. 14, a first crack stopper ST1 and a second crack stopper ST2 can be respectively disposed in one of a region between the first trimming margin line TML1 of the first non-display region NA1 surrounding the display region AA and dummy light-emitting elements, and a region between the trimming line TRL and the second trimming margin line TML2. The first crack stopper ST1 and the second crack stopper ST2 can be formed in a closed loop shape when viewed in a plan view, but the present disclosure is not limited thereto. As an example, at least one of the first crack stopper ST1 and the second crack stopper ST2 can be not formed in a closed loop shape. As an example, the portion where the first crack stopper ST1 is not formed and the portion where the second crack stopper ST2 is not formed may not aligned with each other, without being limited thereto. As an example, the second crack stopper ST2 can be further disposed in a region between the trimming line TRL and the first trimming margin line TML1. As an example, the second crack stopper ST2 can overlap the trimming line TRL, without being limited thereto.

The first and second crack stoppers ST1 and ST2 can be formed on a plurality of inorganic films disposed in the display region AA and the first non-display region NA1. The first and second crack stoppers ST1 and ST2 can be configured by forming a closed loop-shaped opening when viewed in a plan view on the plurality of inorganic films located in the first non-display region NA1. For example, the plurality of inorganic films can be separated by opening-shaped first and second crack stoppers ST1 and ST2. Possibility that cracks occurring through the inorganic film on one side, for example, a portion of the inorganic film close to the first and second trimming margin lines TML1 and TML2, propagate to the other side, for example, a portion of the inorganic film in the display region AA can be blocked in advance by the opening-shaped first and second crack stoppers ST1 and ST2 formed in each inorganic film.

Referring FIGS. 15 and 16, a plurality of stopper layers 111, 114, 116, and 118 can be disposed in the display region AA and the first non-display region NA1. The first to fourth stopper openings 111c, 114a, 116a, and 118a, and the first to fourth auxiliary stopper openings 111d, 114b, 116b, and 118b can be respectively formed in a plurality of stopper layers (111, 114, 116, and 118 in FIG. 15) located in the first non-display region NA1. Further, the first to fourth stopper openings 111c, 114a, 116a, and 118a and the first to fourth auxiliary stopper openings 111d, 114b, 116b, and 118b may not be formed in the plurality of stopper layers 111, 114, 116, and 118 located in the second non-display region NA2 provided with the bending region BA and the pad portion PAD. However, the present disclosure is not limited thereto. The first to fourth stopper openings 111c, 114a, 116a, and 118a can serve as the first crack stopper ST1. The first to fourth auxiliary stopper openings 111d, 114b, 116b, and 118b can serve as the second crack stopper ST2.

The first stopper 111 can include a stacked structure of first and second buffer layers 111a and 111b. However, the present disclosure is not limited thereto.

The first to fourth stopper openings 111c, 114a, 116a, and 118a and the first to fourth auxiliary stopper openings 111d, 114b, 116b, and 118b can block cracks occurring in the first to fourth stopper layers 111, 114, 116, and 118 in the first non-display region NA1 from propagating to the display region AA during laser trimming. The first to fourth stopper openings 111c, 114a, 116a, and 118a and the first to fourth auxiliary stopper openings 111d, 114b, 116b, and 118b formed in each of the first to fourth stopper layers 111, 114, 116, and 118 can be configured in an open shape in which layers under the stopper openings are exposed, but the present disclosure is not limited thereto. For example, portions of upper surfaces of a substrate 110, a second protective layer 113b, a fourth organic insulating layer 115d, and a first optical layer 117a located in the first non-display region NA1 can be exposed by the first to fourth stopper openings 111c, 114a, 116a, and 118a and the first to fourth auxiliary stopper openings 111d, 114b, 116b, and 118b.

The first to fourth stopper openings 111c, 114a, 116a, and 118a and the first to fourth auxiliary stopper openings 111d, 114b, 116b, and 118b can be formed in a closed loop shape surrounding the display region AA in the first non-display region NA1 as shown in FIG. 16 when viewed in a plan view, but the present disclosure is not limited thereto. For example, the closed loop shape can be formed in various shapes such as a line shape, a zigzag shape, and the like when viewed in a plan view. However, the present disclosure is not necessarily limited thereto. For example, each of the first to fourth stopper layers 111, 114, 116, and 118 can have a shape which is independently spaced or separated based on each of the first to fourth stopper openings 111c, 114a, 116a, and 118a and each of the first to fourth auxiliary stopper openings 111d, 114b, 116b, and 118b.

Since each of the first to fourth stopper layers 111, 114, 116, and 118 is independently spaced or separated by the first to fourth stopper openings 111c, 114a, 116a, and 118a and the first to fourth auxiliary stopper openings 111d, 114b, 116b, and 118b, even when cracks occur in the first to fourth stopper layers 111, 114, 116, and 118 in the first non-display region NA1, the cracks may not propagate to the display region AA.

When each of the first to fourth stopper openings 111c, 114a, 116a, and 118a or each of the first to fourth auxiliary stopper openings 111d, 114b, 116b, and 118b is not integrally formed in the closed loop shape in the first non-display region NA1, but is formed only in a partial region of the first non-display region NA1, cracks occurring during laser trimming can propagate to the display region AA through a portion of the stopper layer where the stopper opening is not formed.

The first to fourth stopper openings 111c, 114a, 116a, and 118a and the first to fourth auxiliary stopper openings 111d, 114b, 116b, and 118b can be formed inside the trimming margin line TML in the first non-display region NA1, for example, in the first non-display region NA1 facing the display region AA and a region between the trimming line TRL and the second trimming margin line TML2 outside the trimming line TRL.

For example, the first buffer layer 111a and the second buffer layer 111b can be configured as a first stopper layer 111. For example, the first and second buffer layers 111a and 111b configured as the first stopper layer 111 can be entirely disposed in the display region AA and the non-display region NA. For example, the first stopper layer 111 can be composed of a single layer or multiple layers of silicon oxide (SiOₓ) or silicon nitride (SiNₓ) which is an inorganic film material, but the embodiments of the present disclosure are not limited thereto.

For example, the first stopper opening 111c can be formed in a portion located inside the first trimming margin line TML1 in the first stopper layer 111 located in the first non-display region NA1, and the first auxiliary stopper opening 111d can be formed in a portion located between the second trimming margin line TML2 and the trimming line TRL. The first stopper opening 111c and the first auxiliary stopper opening 111d can be formed as a portion of the first stopper layer 111 is open. Further, the first stopper opening 111c and the first auxiliary stopper opening 111d can be formed in a closed loop shape surrounding the display region AA in the first non-display region NA1 when viewed from above, but the present disclosure is not limited thereto. As an example, the first auxiliary stopper opening 111d can be formed in a portion located between the second trimming margin line TML2 and the first trimming margin line TML1, without being limited thereto. As an example, the first auxiliary stopper opening 111d can overlap the trimming line TRL, without being limited thereto. As an example, the first stopper opening 111c and the first auxiliary stopper opening 111d can be formed simultaneously, or separately, without being limited thereto.

A first organic insulating layer 112 and first and second protective layers 113a and 113b can be disposed on the first stopper layer 111. The second stopper layer 114 can be disposed on the first protective layer 113b. For example, the second stopper layer 114 can be entirely disposed in the display region AA and the non-display region NA. The second stopper layer 114 can also be disposed on a pixel driving circuit PD. For example, the second stopper layer 114 can be composed of a single layer or multiple layers of silicon oxide (SiOₓ) or silicon nitride (SiNₓ) which is an inorganic film material, but the embodiments of the present disclosure are not limited thereto. For example, the second stopper opening 114a can be formed in a portion located inside the trimming margin line TML in the second stopper layer 114 located in the first non-display region NA1. Further, the second auxiliary stopper opening 114b can be formed in a portion between the trimming line TRL and the second trimming margin line TML2.

The second stopper opening 114a and the second auxiliary stopper opening 114b can be formed as a portion of the second stopper layer 114 is open. For example, the second stopper opening 114a and the second auxiliary stopper opening 114b can be formed in a closed loop shape surrounding the display region AA in the first non-display region NA1 when viewed from above, but the present disclosure is not limited thereto.

Further, a first organic insulating layer 115a can be disposed on the second stopper layer 114. The first organic insulating layer 115a can be composed of an organic insulating material, but the embodiments of the present disclosure are not limited thereto.

A plurality of 1-2 connection lines 121b can be disposed on the first organic insulating layer 115a. The plurality of 1-2 connection lines 121b can be connected to or directly connected to the pixel driving circuit PD. For example, some of the 1-2 connection lines 121b can be directly connected to the pixel driving circuit PD through contact holes of the second stopper layer 114. Other 1-2 connection lines 121b can be electrically connected to 1-1 connection lines 121a through contact holes of the second stopper layer 114.

A second organic insulating layer 115b can be disposed on the plurality of 1-2 connection lines 121b. The second organic insulating layer 115b can be entirely disposed in the display region AA and the non-display region NA, but the embodiments of the present disclosure are not limited thereto.

A plurality of 1-3 connection lines 121c can be disposed on the second organic insulating layer 115b. The plurality of 1-3 connection lines 121c can be electrically connected to the plurality of 1-2 connection lines 121b. For example, the 1-3 connection lines 121c can be electrically connected to the 1-2 connection lines 121b through contact holes of the second organic insulating layer 115b.

A third organic insulating layer 115c can be disposed on the plurality of 1-3 connection lines 121c. The third organic insulating layer 115c can be disposed in the remaining regions excluding the bending region BA, but the embodiments of the present disclosure are not limited thereto.

A plurality of 1-4 connection lines 121d can be disposed on the third organic insulating layer 115c. The plurality of 1-4 connection lines 121d can be electrically connected to the plurality of 1-3 connection lines 121c. For example, the 1-4 connection lines 121d can be electrically connected to the 1-3 connection lines 121c through contact holes of the third organic insulating layer 115c.

The fourth organic insulating layer 115d can be disposed on the plurality of 1-4 connection lines 121d. The fourth organic insulating layer 115d can be disposed in the remaining regions excluding the bending region BA, but the embodiments of the present disclosure are not limited thereto. The fourth organic insulating layer 115d can be disposed in the display region AA, the first non-display region NA1, and the second non-display region NA2, but the embodiments of the present disclosure are not limited thereto.

The third stopper layer 116 can be disposed on the fourth organic insulating layer 115d including a first electrode CE1 and a bank BNK. For example, the third stopper layer 116 can be entirely disposed in the display region AA and the non-display region NA. For example, the third stopper layer 116 can be composed of a single layer or multiple layers of silicon oxide (SiOₓ) or silicon nitride (SiNₓ) which is an inorganic film material, but the embodiments of the present disclosure are not limited thereto. For example, the third stopper opening 116a can be formed in a portion located inside the first trimming margin line TML1 in the third stopper layer 116 located in the first non-display region NA1. Further, the third auxiliary stopper opening 116b can be formed in a portion between the second trimming margin line TML2 and the trimming line TRL.

The third stopper opening 116a and the third auxiliary stopper opening 116b can be formed as a portion of the third stopper layer 116 is open. For example, the third stopper opening 116a and the third auxiliary stopper opening 116b can be formed in a closed loop shape surrounding the display region AA when viewed in a plan view, but the present disclosure is not limited thereto.

According to the example embodiments of the present disclosure, the third stopper layer 116 can be disposed on a plurality of signal lines TL, a plurality of first electrodes CE1, a plurality of contact electrodes CCE, and the third insulating layer 115c. For example, the third stopper layer 116 can be disposed in the display region AA, the first non-display region NA1, and the second non-display region NA2. The third stopper layer 116 can be a passivation layer, but the present disclosure is not limited thereto.

The third stopper layer 116 can be disposed to cover the remaining regions excluding regions where the bending region BA, a plurality of pad electrodes PE, and a solder pattern SDP are disposed. Accordingly, the penetration of moisture or impurities into the light-emitting element ED can be prevented.

The fourth stopper layer 118 can be disposed on a second electrode CE2 and the first optical layer 117a. For example, the fourth stopper layer 118 can be entirely disposed in the display region AA and the non-display region NA. For example, the fourth stopper layer 118 can be composed of a single layer or multiple layers of silicon oxide (SiOₓ) or silicon nitride (SiNₓ) which is an inorganic film material, but the embodiments of the present disclosure are not limited thereto. For example, the fourth stopper opening 118a can be formed in a portion located inside the trimming margin line TML in the fourth stopper layer 118 located in the first non-display region NA1. Further, the fourth auxiliary stopper opening 118b can be formed in a portion between the second trimming margin line TML2 and the trimming line TRL.

The fourth stopper opening 118a and the fourth auxiliary stopper opening 118b can be formed as a portion of the fourth stopper layer 118 is open. The fourth stopper opening 118a and the fourth auxiliary stopper opening 118b can be formed in a closed loop shape surrounding the display region AA when viewed in a plan view, but are not limited thereto. Further, a third optical layer 117c can be disposed on the fourth stopper layer 118 on the second electrode CE2.

According to another example embodiment of the present disclosure, as shown in FIGS. 14 to 16, closed loop-shaped first to fourth stopper openings 111c, 114a, 116a, and 118a and first to fourth auxiliary stopper openings 111d, 114b, 116b, and 118b when viewed from above can be respectively disposed in portions of the first to fourth stopper layers 111, 114, 116, and 118 disposed in the first non-display region NA1.

Each of the first to fourth stopper openings 111c, 114a, 116a, and 118a and each of the first to fourth auxiliary stopper openings 111d, 114b, 116b, and 118b can be formed in a collinear line in a vertical direction with respect to the substrate. However, the present disclosure is not necessarily limited thereto. As an example, the first to fourth stopper openings 111c, 114a, 116a, and 118a can at least partially overlap each other, or may not overlap each other, without being limited thereto. As an example, the first to fourth auxiliary stopper openings 111d, 114b, 116b, and 118b can at least partially overlap each other, or may not overlap each other, without being limited thereto. As an example, at least one of the first to fourth stopper openings 111c, 114a, 116a, and 118a can be omitted, or at least one of the first to fourth auxiliary stopper openings 111d, 114b, 116b, and 118b can be omitted. As an example, at least one of the first to fourth stopper openings 111c, 114a, 116a, and 118a can overlap at least one of the first to fourth auxiliary stopper openings 111d, 114b, 116b, and 118b, without being limited thereto. As an example, the first to fourth stopper openings 111c, 114a, 116a, and 118a and the first to fourth auxiliary stopper openings 111d, 114b, 116b, and 118b can all have the same size or different sizes, without being limited thereto.

According to the embodiment of the present disclosure, even when the cracks occur in the first to fourth stopper layers 111, 114, 116, and 118 located in the first non-display region NA1 during laser trimming on the trimming line TRL, since the cracks may not propagate to the display region AA by the first to fourth stopper openings 111c, 114a, 116a, and 118a and the first to fourth auxiliary stopper openings 111d, 114b, 116b, and 118b, the reliability and yield of the display device can be enhanced. Although it is illustrated that each of the first to fourth stopper layers 111, 114, 116, and 118 comprises one stopper opening or two stop openings, embodiments are not limited thereto. As an example, each of the first to fourth stopper layers 111, 114, 116, and 118 can comprise three or more openings. As an example, the first to fourth stopper layers 111, 114, 116, and 118 can comprise the same number of openings or different number of openings, without being limited thereto.

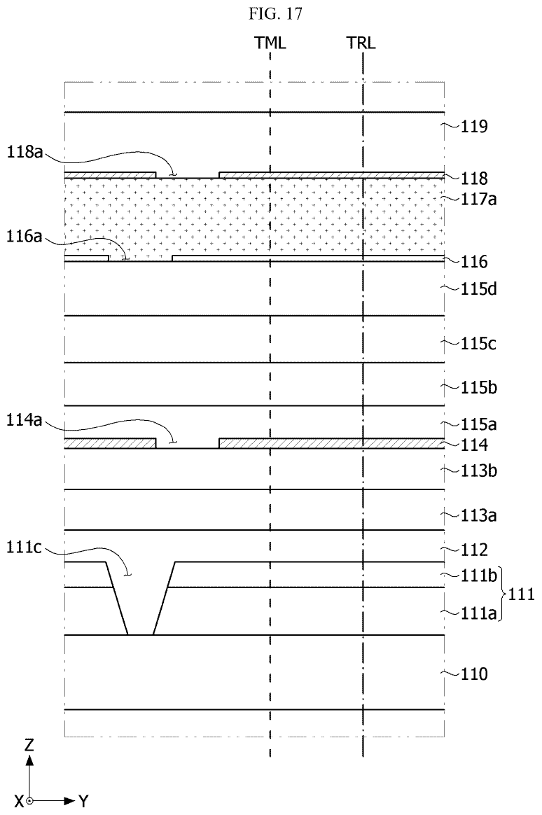

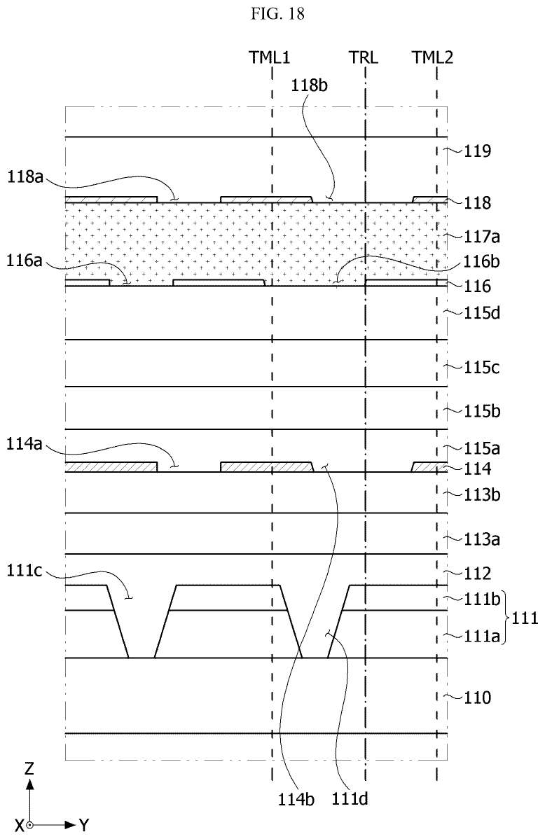

FIG. 17 is an enlarged cross-sectional view of a display device according to still another example embodiment of the present disclosure. FIG. 18 is an enlarged cross-sectional view of a display device according to yet another example embodiment of the present disclosure.

FIG. 17 is still another embodiment of one example embodiment of the present disclosure in FIGS. 11 to 13, and shows an example in which first to fourth stopper openings 111c, 114a, 116a, and 118a are disposed in a non-collinear line in a vertical direction, for example, disposed to be offset with respect to the substrate. However, the present disclosure is not limited thereto.

FIG. 18 is yet another embodiment of another example embodiment of the present disclosure in FIGS. 14 to 16, and shows an example in which first to fourth stopper openings 111c, 114a, 116a, and 118a and first to fourth auxiliary stopper openings 111d, 114b, 116b, and 118b are disposed in a non-collinear line in a vertical direction, for example, disposed to be offset in a vertical direction with respect to the substrate. However, the present disclosure is not limited thereto.

According to still another example embodiment of the present disclosure, as shown in FIG. 17, closed loop-shaped first to fourth stopper openings 111c, 114a, 116a, and 118a when viewed from above can be respectively formed in portions of first to fourth stopper layers 111, 114, 116, and 118 disposed in a first non-display region NA1.

The first to fourth stopper openings 111c, 114a, 116a, and 118a can be respectively formed in the first to fourth stopper layers 111, 114, 116, and 118 in the first non-display region NA1 located between a trimming margin line TML in the first non-display region NA1 and a display region AA. Further, the first to fourth stopper openings 111c, 114a, 116a, 118a can be formed in the non-collinear line in the vertical direction with respect to the substrate. For example, at least one or more of the first to fourth stopper openings 111c, 114a, 116a and 118a can be formed in the non-collinear line with the remaining stopper openings which are vertically located. However, the present disclosure is not necessarily limited thereto.

According to still embodiment of the present disclosure, even when cracks occur in the first to fourth stopper layers 111, 114, 116, and 118 located in the first non-display region NA1 during laser trimming on a trimming line TRL, since the cracks may not propagate to the display region AA by the first to fourth stopper openings 111c, 114a, 116a, and 118a, the reliability and yield of the display device can be enhanced.

As shown in FIG. 18, according to yet another example embodiment of the present disclosure, closed loop-shaped first to fourth stopper openings 111c, 114a, 116a, and 118a and first to fourth auxiliary stopper openings 111d, 114b, 116b, and 118b when viewed from above can be respectively disposed in portions of first to fourth stopper layers 111, 114, 116, and 118 disposed in a first non-display region NA1.

Each of the first to fourth stopper openings 111c, 114a, 116a, and 118a and each of the first to fourth auxiliary stopper openings 111d, 114b, 116b, and 118b can be formed in the non-collinear line in the vertical direction with respect to the substrate. For example, at least one or more of each of the first to fourth stopper openings 111c, 114a, 116a, and 118a and each of the first to fourth auxiliary stopper openings 111d, 114b, 116b, and 118b can be formed in the non-collinear line with the remaining stopper openings which are vertically located. However, the present disclosure is not necessarily limited thereto.

According to yet embodiment of the present disclosure, even when cracks occur in the first to fourth stopper layers 111, 114, 116, and 118 located in the first non-display region NA1 during laser trimming on a trimming line TRL, since the cracks may not propagate to a display region AA by the first to fourth stopper openings 111c, 114a, 116a, and 118a and the first to fourth auxiliary stopper openings 111d, 114b, 116b, and 118b, the reliability and yield of the display device can be enhanced.

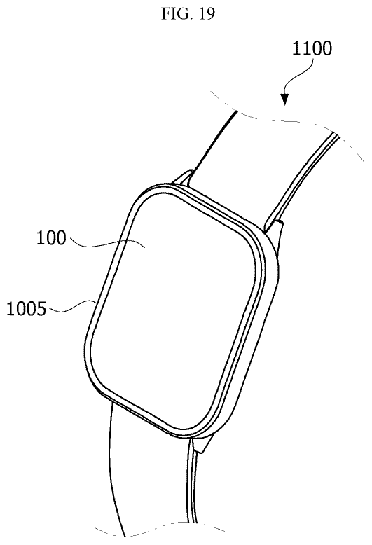

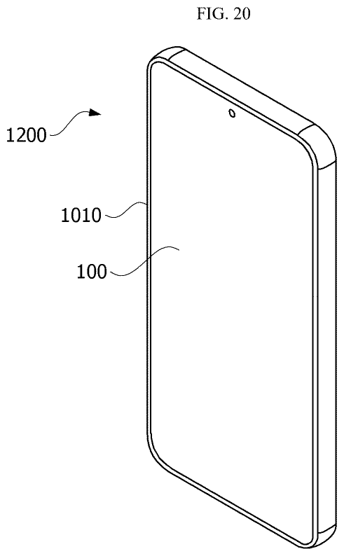

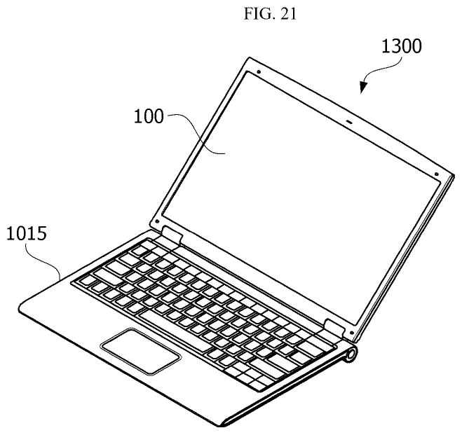

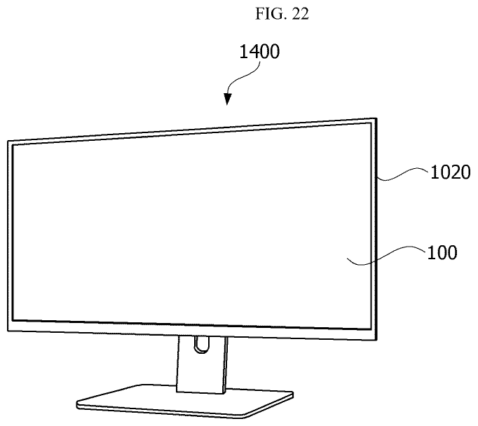

FIGS. 19 to 22 are views showing devices to which the display devices according to the example embodiments of the present disclosure are applied.

Referring to FIGS. 19 to 22, the display devices 1000 according to the example embodiments of the present disclosure can be included in various devices or electronic devices. For example, referring to FIGS. 19 to 22, various electronic devices can include a wearable device 1100, a mobile device 1200, a notebook 1300, and a monitor or television (TV) 1400, but the embodiments of the present disclosure are not limited thereto.

The wearable device 1100, the mobile device 1200, the notebook 1300, and the monitor or TV 1400 can respectively include case portions 1005, 1010, 1015, and 1020, and the above-described display panels 100 and display devices 1000 according to the example embodiments of the present disclosure described in FIGS. 11 to 18.

The display device according to the example embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present disclosure can be applied to an organic light emitting lighting device or an inorganic light emitting lighting device.

According to the example embodiments of the present disclosure, as a stopper region is formed in an inorganic film in a non-display region between a trimming margin line and a display region and/or in a non-display region between a trimming line and the trimming margin line, cracks occurring in the inorganic film during trimming can be effectively blocked from propagating to the display region.

According to the example embodiments of the present disclosure, since a stopper region is configured to separate the inorganic films disposed in the trimming margin line and the display region, and thus cracks occurring in the inorganic film during trimming are prevented from propagating to the display region by the stopper region, the reliability and yield of the display device can be enhanced.

The effects according to the example embodiments of the present disclosure are not limited to the above-mentioned effects, and other effects which are not mentioned can be clearly understood by those skilled in the art from the disclosure to be described below.

The display device according to various example embodiments of the present disclosure can be described as follows.

A display device according to various example embodiments of the present disclosure can comprise a substrate including a display region and a non-display region; a pixel driving circuit disposed on the substrate; a plurality of light-emitting elements disposed on the substrate and electrically connected to the pixel driving circuit; an optical layer disposed on the substrate and located on side surfaces of the plurality of light-emitting elements; and a plurality of stopper layers disposed under the pixel driving circuit, between the pixel driving circuit and the plurality of light-emitting elements, and in at least one of the display region and the non-display region under and on the light-emitting elements, wherein at least one of the plurality of stopper layers includes a stopper region disposed in the non-display region.

According to one example embodiment of the present disclosure, the plurality of stopper layers can include a first stopper layer disposed on the substrate under the pixel driving circuit; a second stopper layer disposed on a first insulating layer disposed on the pixel driving circuit; a third stopper layer disposed on a second insulating layer disposed on the second stopper layer; and a fourth stopper layer disposed on the plurality of light-emitting elements and the optical layer.

According to one example embodiment of the present disclosure, the stopper region can be disposed in the first to fourth stopper layers in the non-display region.

According to one example embodiment of the present disclosure, the stopper region can be formed in a closed loop shape surrounding the display region.

According to one example embodiment of the present disclosure, the closed loop shape can include a line shape or a zigzag shape.

According to one example embodiment of the present disclosure, the stopper region can further include an opening in at least one of the first to fourth stopper layers.

According to one example embodiment of the present disclosure, one or more of the first to fourth stopper layers can be spaced apart from each other by the stopper region in the non-display region.

According to one example embodiment of the present disclosure, the non-display region can include one of a region between a trimming line and a trimming margin line and a region between the trimming margin line and the display region.

According to one example embodiment of the present disclosure, the stopper region can be configured in the non-display region of at least one of the first to fourth stopper layers between the display region and the trimming margin line.

According to one example embodiment of the present disclosure, the stopper region can be configured in one of the non-display region at one side of the display region and the trimming margin line, and the non-display region between the trimming margin line and the trimming line.

According to one example embodiment of the present disclosure, the stopper regions can be disposed in a collinear line or non-collinear line on the substrate in a vertical direction with respect to the substrate.

According to one example embodiment of the present disclosure, each of the first to fourth stopper layers can include an inorganic film.

According to one example embodiment of the present disclosure, each of the first and second insulating layers can include at least one organic insulating layer.

According to one example embodiment of the present disclosure, the display device can include a plurality of banks that support the plurality of light-emitting elements; a plurality of first electrodes disposed between the plurality of banks and the plurality of light-emitting elements; and a plurality of signal line that electrically connect the plurality of first electrodes to the pixel driving circuit.

According to one example embodiment of the present disclosure, the display device can further include a pattern layer disposed on the plurality of first electrodes, wherein the plurality of first electrodes and the plurality of light-emitting elements are connected by eutectic bonding using the pattern layer.

According to one example embodiment of the present disclosure, the display device can further include a plurality of contact electrodes electrically connected to the pixel driving circuit; and one or more second electrodes disposed on the optical layer and electrically connected to the plurality of contact electrodes.

According to one example embodiment of the present disclosure, the display device can further include a black matrix disposed on the fourth stopper layer and including a plurality of through holes; and a cover layer disposed on the black matrix.

According to one example embodiment of the present disclosure, the display device can further include an auxiliary optical layer disposed between the fourth stopper layer on the optical layer in the display region and the black matrix.

According to one example embodiment of the present disclosure, the plurality of light-emitting elements can include micro light-emitting elements, and the micro light-emitting elements have a vertical structure.

A display device according to various example embodiments of the present disclosure can comprise a substrate including a display region and a non-display region; a first stopper layer disposed on the substrate and having a first stopper region in the non-display region; a pixel driving circuit disposed on the first stopper layer and a first insulating layer disposed on the first stopper layer; a second stopper layer disposed on the first insulating layer and having a second stopper region in the non-display region; a second insulating layer disposed on the second stopper layer; a third stopper layer disposed on the second insulating layer and having a third stopper region in the non-display region; a plurality of light-emitting elements disposed on the third stopper layer and electrically connected to the pixel driving circuit; an optical layer disposed on the third stopper layer; and a fourth stopper layer disposed on the optical layer and having a fourth stopper region in the non-display region.

According to one example embodiment of the present disclosure, the first to fourth stopper regions can further include an opening formed in each of the first to fourth stopper layers.

According to one example embodiment of the present disclosure, the first to fourth stopper layers can be spaced apart from each other by the first to fourth stopper regions.

Although embodiments of the present disclosure have been described in more detail with reference to the accompanying drawings, the present disclosure is not necessarily limited to the embodiments, and various modifications can be carried out without departing from the technical spirit of the present disclosure.

Therefore, the embodiments disclosed in the present disclosure are not intended to limited the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A display device comprising:
a substrate including a display region and a non-display region;
a plurality of light-emitting elements disposed on the substrate;
a plurality of stopper layers disposed under or on the plurality of light-emitting elements,
wherein at least one of the plurality of stopper layers includes a stopper region disposed in the non-display region.

2. The display device of claim 1, further comprising a pixel driving circuit disposed on the substrate and electrically connected to the plurality of light-emitting elements,
wherein the plurality of stopper layers are further disposed under or on the pixel driving circuit.

3. The display device of claim 2, wherein the plurality of stopper layers include:
a first stopper layer disposed on the substrate under the pixel driving circuit;
a second stopper layer disposed on a first insulating layer disposed on the first stopper layer;
a third stopper layer disposed on a second insulating layer disposed on the second stopper layer; and
a fourth stopper layer disposed on the plurality of light-emitting elements,
wherein each of the first to fourth stopper layers includes an inorganic film,
wherein each of the first and second insulating layers includes at least one organic insulating layer, and
wherein the stopper region is disposed in the first to fourth stopper layers in the non-display region.

4. The display device of claim 1, wherein the stopper region is formed in a closed loop shape around the display region, and the closed loop shape includes a line shape or a zigzag shape.

5. The display device of claim 3, wherein the stopper region includes an opening in the at least one of the first to fourth stopper layers, and the at least one of the first to fourth stopper layers is divided into separate parts by the stopper region in the non-display region.

6. The display device of claim 1, wherein the non-display region includes a region between a trimming line and a trimming margin line disposed inside the trimming line and a region between the trimming margin line and the display region, and
wherein the stopper region is configured in the region between the trimming margin line and the display region.

7. The display device of claim 6, further comprising dummy light-emitting elements in the non-display region,
wherein the stopper region is provided in a region between the trimming margin line and the dummy light-emitting elements.

8. The display device of claim 6, wherein the stopper region is provided in one of the region between the trimming line and the trimming margin line and the region between the trimming margin line and the display region.

9. The display device of claim 8, wherein the at least one of the plurality of stopper layers further comprises another stopper region configured in the other of the region between the trimming line and the trimming margin line and the region between the trimming margin line and the display region.

10. The display device of claim 1, wherein the stopper regions included in at least two of the plurality of stopper layers are disposed in a collinear line or non-collinear line in a vertical direction with respect to the substrate.

11. The display device of claim 2, further comprising:
a plurality of banks that support the plurality of light-emitting elements;
a plurality of first electrodes disposed between the plurality of banks and the plurality of light-emitting elements; and
a plurality of signal line that electrically connect the plurality of first electrodes to the pixel driving circuit.

12. The display device of claim 11, further comprising a pattern layer disposed on the plurality of first electrodes,
wherein the plurality of first electrodes and the plurality of light-emitting elements are connected by eutectic bonding using the pattern layer.

13. The display device of claim 2, further comprising:
a plurality of contact electrodes electrically connected to the pixel driving circuit; and
one or more second electrodes disposed on the plurality of light-emitting elements and electrically connected to the plurality of contact electrodes.

14. The display device of claim 3, further comprising:
a black matrix disposed on the fourth stopper layer and including a plurality of through holes;
a cover layer disposed on the black matrix;
an optical layer disposed on the substrate and located on side surfaces of the plurality of light-emitting elements, the fourth stopper layer being disposed on the plurality of light-emitting elements and the optical layer; and
an auxiliary optical layer disposed between the fourth stopper layer on the optical layer in the display region and the black matrix.

15. The display device of claim 14, wherein the optical layer and the auxiliary optical layer include an organic insulating material in which fine particles are dispersed.

16. The display device of claim 1, wherein the plurality of light-emitting elements include micro light-emitting elements, and
the micro light-emitting elements have a vertical structure.

17. A display device comprising:
a substrate including a display region and a non-display region;
a first stopper layer disposed on the substrate and having a first stopper region in the non-display region;
a pixel driving circuit disposed on the first stopper layer and a first insulating layer disposed on the first stopper layer;
a second stopper layer disposed on the first insulating layer and having a second stopper region in the non-display region;
a second insulating layer disposed on the second stopper layer;
a third stopper layer disposed on the second insulating layer and having a third stopper region in the non-display region;
a plurality of light-emitting elements disposed on the third stopper layer and electrically connected to the pixel driving circuit;
an optical layer disposed on the third stopper layer; and
a fourth stopper layer disposed on the optical layer and having a fourth stopper region in the non-display region.

18. The display device of claim 17, wherein the first to fourth stopper regions include an opening formed in each of the first to fourth stopper layers,
wherein each of the first to fourth stopper layers is divided into separate parts by respective stopper region among the first to fourth stopper regions, and
wherein the first to fourth stopper regions are provided in a region between the display region and a trimming margin line in the non-display region, or provided in the region between the display region and the trimming margin line and a region between the trimming margin line and a trimming line disposed outside the trimming margin line.

19. A display device, comprising:
a substrate including a display region and a non-display region;
a plurality of light-emitting elements disposed on the substrate; and
a stopper layer disposed under or on the plurality of light-emitting elements,
wherein the stopper layer includes an opening disposed in the non-display region.

20. The display device of claim 19, wherein the opening of the stopper layer is formed in a closed loop shape around the display region, and
wherein the opening of the stopper layer is formed in at least one of a region between a trimming line and a trimming margin line disposed inside the trimming line and a region between the trimming margin line and the display region.
